(19) United States
(12) Patent Application Publication
(10) Pub. No.: US 2013/0152853 A1
(43) Pub. Date: Jun. 20, 2013

(54) FILM-FORMING APPARATUS AND FILM-FORMING METHOD

(71) Applicants: NuFlare Technology, Inc., Numazu-shi (JP); Central Research Institute of Electric Power Industry, Tokyo (JP); Denso Corporation, Kariya-Shi (JP); Ayumu ADACHI, Toyota-shi (JP); Koichi NISHIKAWA, Nagakute-shi (JP)

(72) Inventors: Kunihiko SUZUKI, Sunto-gun (JP); Yuusuke SATO, Tokyo (JP); Hideki ITO, Yokosuka-shi (JP); Hidekazu TSUCHIDA, Yokosuka-shi (JP); Isaho KAMATA, Tokyo (JP); Masahiko ITO, Yokosuka-shi (JP); Masami NAITO, Inazawa-shi (JP); Hiroaki FUJIBAYASHI, Zushi-shi (JP); Ayumu ADACHI, Toyota-shi (JP); Koichi NISHIKAWA, Nagoya-shi (JP)

(73) Assignees: Ayumu ADACHI, Toyota-shi (JP); Koichi NISHIKAWA, Nagakute-shi (JP); Denso Corporation, Kariya-Shi (JP); Central Research Institute of Electric Power Industry, Tokyo (JP); NuFlare Technology, Inc., Numazu-shi (JP)

(21) Appl. No.: 13/714,918

(22) Filed: Dec. 14, 2012

(30) Foreign Application Priority Data
Dec. 15, 2011 (JP) 2011-274703
Apr. 12, 2012 (JP) 2012-265217

(51) Int. Cl. C30B 25/16; C30B 25/14

(52) U.S. Cl. CPC C30B 25/165; C30B 25/14
USPC 117/88; 118/715; 118/724

(57) ABSTRACT

A film-forming apparatus 100 supplies a plurality of gases toward a substrate 101 in a chamber 103 using a shower plate 124. The shower plate 124 has a plurality of gas flow paths 121 extending within the shower plate along a first face of the substrate 101 side and connected to gas pipes 131 supplying a plurality of gases, and a plurality of gas jetting holes 129 bored such that the plurality of gas flow paths 121 and the chamber 103 communicate with each other on the first face side. In the film-forming apparatus 100, the plurality of gases supplied from the gas pipes 131 to the plurality of gas flow paths 121 of the shower plate 124 are supplied from the gas jetting holes 129 to the substrate 101 without being mixed inside of and vicinity of the shower plate 124.

### CROSS-REFERENCE TO THE RELATED APPLICATION

The entire disclosure of the Japanese Patent Applications No. 2011-274703, filed on Dec. 15, 2011 including specification, claims, drawings, and summary, on which the Convention priority of the present application is based, are incorporated herein in its entirety.

### FIELD OF THE INVENTION

The present invention relates to a film-forming apparatus and a film-forming method.

### BACKGROUND ART

Epitaxial growth technique for used depositing a monocrystalline film on a substrate such as a wafer is conventionally used to produce a semiconductor device such as a power device (e.g., IGBT (Insulated Gate Bipolar Transistor)) requiring a relatively thick crystalline film.

In the case of film-forming apparatus used in an epitaxial growth technique, a wafer is placed inside a film-forming chamber maintained at an atmospheric pressure or a reduced pressure, and a source gas is supplied into the film-forming chamber while the wafer is heated. As a result of this process, a pyrolytic reaction or a hydrogen reduction reaction of the source gas occurs on the surface of the wafer so that an epitaxial film is formed on the wafer.

In order to produce a thick epitaxial film in high yield, a fresh source gas needs to be continuously brought into contact with the surface of a grown on a wafer while the wafer is rotated uniformly heated substrate to increase a film-forming rate. Therefore, in the case of a conventional film-forming apparatus, a film is epitaxially at a high speed (see, for example, Japanese Patent Application Laid-Open No. H05-152207).

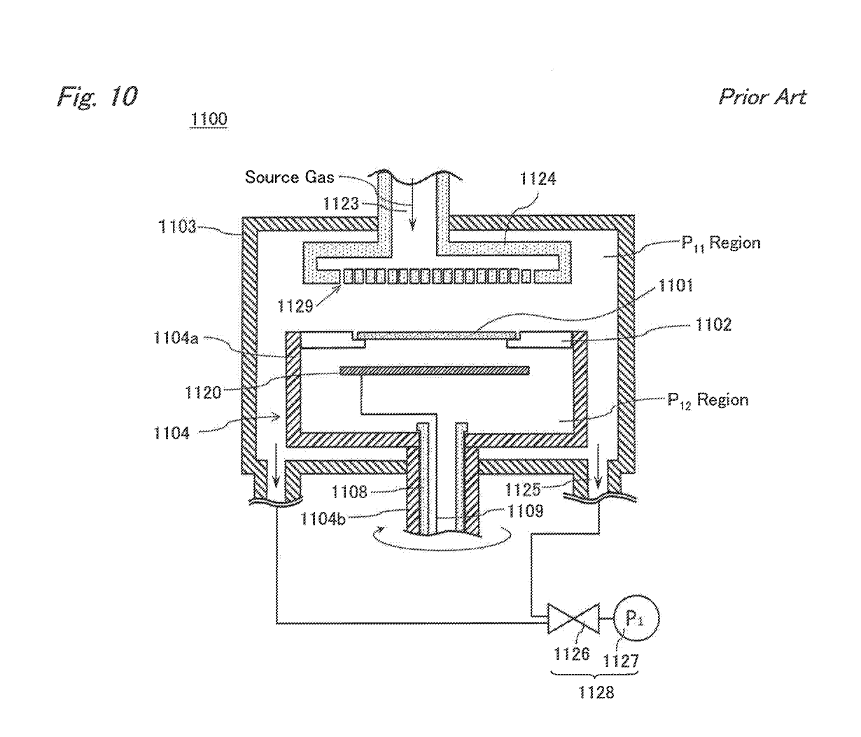

FIG. 10 is a schematic cross-sectional view of a conventional film-forming apparatus.

A conventional film-forming apparatus 1100 includes a chamber 1103 used as a film-forming chamber (otherwise known as a reaction chamber) for forming an epitaxial film on a wafer 1101 as a semiconductor substrate by vapor phase growth reaction. A gas supply portion 1123 used for supplying a source gas for growing the crystalline film on the surface of the heated wafer 1101 is provided in the upper part of the chamber 1103. The gas supply portion 1123 is connected with a shower plate 1124 on which a plurality of gas jetting holes 1129 functioning as through-holes for the source gas are positioned. By using the shower plate 1124, fluidization of the raw material gas within the chamber 1103 can be made uniform and the raw material gas can be supplied to the wafer 1101 uniformly.

As the raw material gas, when a SiC (silicone nitride) epitaxial film should be formed on a surface of the wafer 1101, for example, a source gas for silicon (Si) such as silane (SiH₄) and a source gas for carbon such as propane (C₃H₄) are mixed with a hydrogen (H₂) gas which is a carrier gas to be used. A raw material gas obtained by mixing these gases is supplied from the shower plate 1124 toward the wafer 1101 in a shower fashion.

Incidentally, when a GaN (gallium nitride) epitaxial film should be formed using metal organic chemical vapor deposition method (MOCVD method), it is possible to use an apparatus similar to the film-forming apparatus 1100. In that case, as the raw material gas, for example, a gas obtained by mixing a source gas for gallium (Ga) such as a trimethyl gallium (TMG) and a source gas for nitrogen (N) such as ammonia (NH₃) with a hydrogen gas is used. It is possible to supply the source gas from the shower plate 1124 toward the wafer 1101 in a shower fashion to form a GaN epitaxial film on the wafer 1101.

A plurality of gas discharge portions 1125 that discharge the source gas subjected to reaction, are provided in the bottom of the chamber 1103. The gas discharge portions 1125 are connected with a discharge system 1128 comprising of an adjustment valve 1126 and a vacuum pump 1127. A ring-shaped susceptor 1102 for holding the wafer 1101 is provided above a rotating portion 1104 in the chamber 1103. The susceptor 1102 has a counterbore provided thereon so that the outer periphery of the wafer 1101 can be positioned in the counterbore.

The rotating portion 1104 has a cylindrical portion 1104a and a rotating shaft 1104b. The rotating shaft 1104b rotates, and then the susceptor 1102 will be rotated via the cylindrical portion 1104a.

As seen in FIG. 10, the cylindrical portion 1104a includes an opening in the upper part of the portion. The susceptor 1102 is positioned in the opening of the cylindrical portion 1104a; the wafer 1101 is placed on the susceptor 1102. As the opening is covered with the susceptor 1102 and the wafer 1101a hollow region (herein after P₁₂ region) is formed that is separated from the P₁₁ region in the chamber 1103.

A heater 1120 is provided in the P₁₂ region. Electricity is conducted to the heater 1120 via wires 1109 in a cylindrical shaped shaft 1108 within the rotating shaft 1104b, as a result the back surface of the wafer 1101 is heated by the heater 1120.

The rotating shaft 1104b of the rotating portion 1104 is connected with the rotating system (not shown) positioned outside of the chamber 1103. The cylindrical portion 1104a is rotated, as a result the susceptor 1102 is rotated via the cylindrical portion 1104a, and the wafer 1101 is rotated with the susceptor 1102.

A transfer robot (not shown) is used for transferring the wafer 1101 into, or out of the chamber 1103 as seen in FIG. 10. In this case, a substrate elevating means (not shown) is used for moving the wafer 1101 up and down. When the wafer 1101 is transferred out of the chamber 1103, for example, the wafer 1101 is moved in an upwards direction via the substrate elevating means to take it away from the susceptor 1102. The wafer 1101 is then transferred to the transfer robot, and then the wafer 1101 is transferred out of the chamber 1103. When the wafer 1101 is transferred into the chamber 1103, the wafer 1101 is transferred from the transfer robot to the substrate elevating means, and then the wafer 1101 is lowered via the substrate elevating means by the elevator to be placed on the susceptor 1102.

In the conventional film-forming apparatus 1100 shown in FIG. 10, a shower plate 1124 is used so as to be capable of making flow of the raw material gas within the chamber 1103 uniform to supply the raw material gas on to the wafer 1101 uniformly. Then, an epitaxial film having uniform electrical characteristics or the like is formed on a whole face of the wafer 1101.

In the film-forming apparatus 1100, heating of the wafer 1101 by a heater 1120 is performed in formation of the epitaxial film. In that case, the shower plate 1124 may also be heated up to a high temperature.

For example, a reaction gas obtained by mixing a source gas for silicon (Si) such as silane (SiH₄) and a source gas for carbon (C) such as propane (C₃H₈) with each other is present within the shower plate 1124, as described above. Then, the reaction gas is supplied from a face of the shower plate 1124 positioned on the side of the wafer 1101 toward the wafer 1101.

As a result, such a problem occurs that the reaction gas reacts at the shower plate 1124 so that a film is formed on the inside of or the surface of the shower plate 1124. When the film falls off, it forms a foreign matter, which results in lowering of manufacturing yield of an epitaxial wafer. Further, such a case may occur that the reaction gas whose temperature has been raised to a high temperature and which has been supplied from the shower plate 1124 reacts in the middle of arrival at the surface of the wafer 1101, so that the epitaxial wafer cannot be manufactured efficiently.

In view of these circumstances, in a film-forming apparatus and a film-forming method utilizing an epitaxial growth technique, a technique of preventing reaction of raw material gases inside or on the surface of the shower place having a function of rectifying the raw material gases has been demanded.

An object of the present invention is to provide a film-forming apparatus and a film-forming method where reaction of raw material gases between them on a shower plate is inhibited.

Other challenges and advantages of the present invention are apparent from the following description.

### SUMMARY OF THE INVENTION

According to one aspect of this invention, a film-forming apparatus including a film-forming chamber, a shower plate provided at an upper section of the film-forming chamber and through which gases supplied to the film-forming chamber pass. The shower plate has a first face directed to the inside of the film-forming chamber, a second face opposed to the first face and directed to the outside of the film-forming chamber, a plurality of gas flow paths extending between the first face and the second face along the first and second faces, and a plurality of gas jetting holes which causes the plurality of gas flow paths and the first face to communicate with each other. The gases supplied from respective ends of the plurality of gas flow paths are jetted from the plurality of gas jetting holes toward the inside of the film-forming chamber.

The film-forming apparatus according to the present invention, further preferably comprises a gas supply control mechanism. The gas supply control mechanism controls a timing of supplying a first gas to at least one of the plurality of gas flow paths and a timing of supplying a second gas to another gas flow path of the plurality of gas flow paths.

In the film-forming apparatus according to the present invention, the shower plate is preferably provided with a colling mechanism on the second face.

The colling mechanism preferably provided in the shower plate at a position close to the first face.

In another aspect of the present invention, a closing member which closes at least some of the plurality of gas jetting holes causing the gas flow paths and the film-forming chamber to communicate with each other may be provided. At this time, each of the gas flow paths extends through the inside of the shower plate in a predetermined direction along the first face. The closing member may be provided with a rod-shaped member which is inserted into each of the gas flow paths to close at least some of the plurality of gas jetting holes causing the gas flow path and the film-forming chamber to communicate with each other and has through-holed formed so as to cause the remaining gas jetting holes and the gas flow path to communicate with each other.

Further, the closing member may be a lid or a screw.

The film-forming method according to the present invention, is characterized in that the sample is disposed in the film-forming chamber, the shower plate has a plurality of gas flow paths extending in the shower plate along the first face directed to the side of the sample and a plurality of gas jetting holes bored such that the plurality of gas flow paths communicate with the inside of the film-forming chamber on the side of the first face, and the plurality of gases are supplied to the plurality of gas flow paths of the shower plate, so that the plurality of gases are supplied from the plurality of gas jetting holes toward the sample.

### BRIEF DESCRIPTION OF THE DIAGRAMS

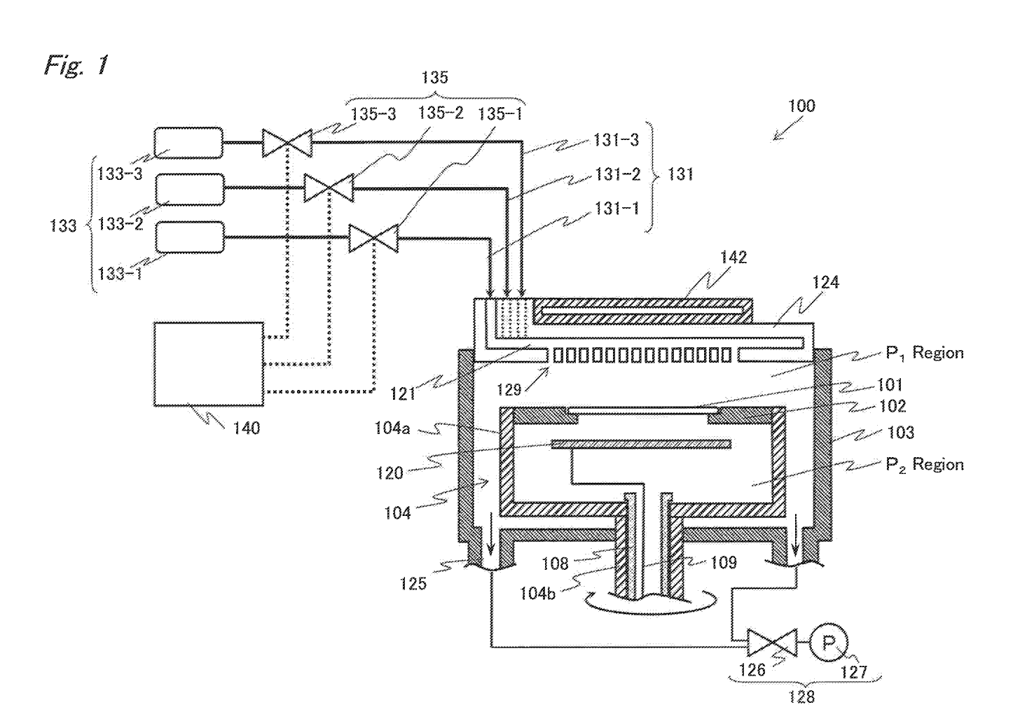

FIG. 1 is a schematic view of a single wafer film-forming apparatus according to the embodiment 1 of the present invention.

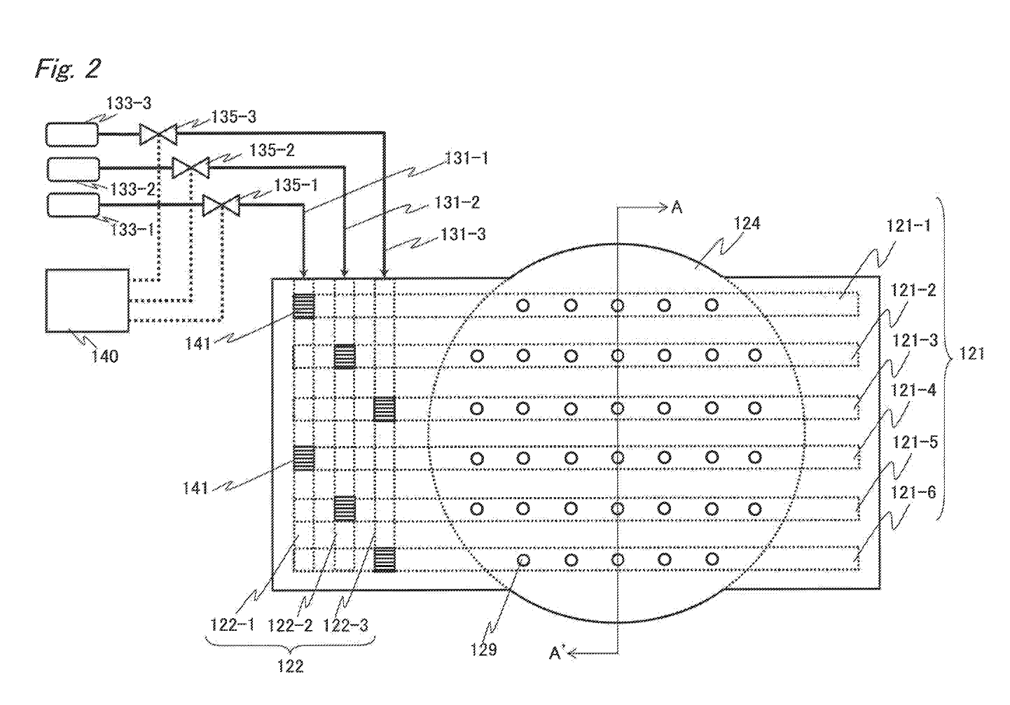

FIG. 2 is a schematic view of a shower plate of a film-forming apparatus according to the embodiment 1 of the present invention.

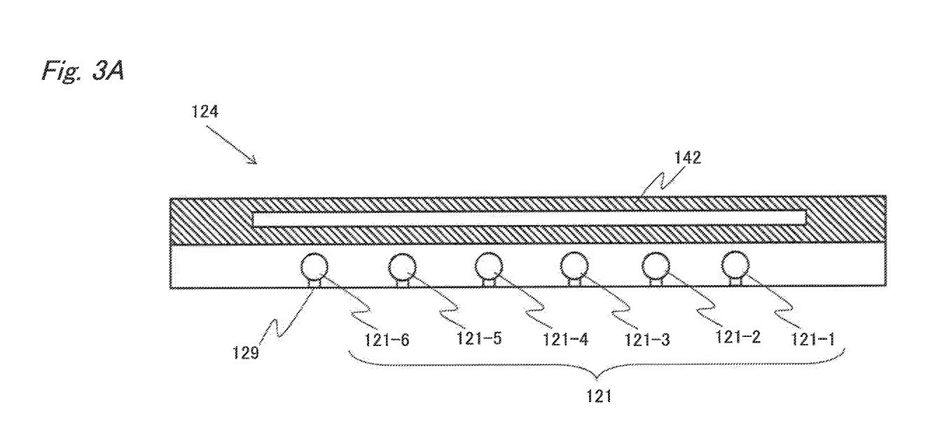

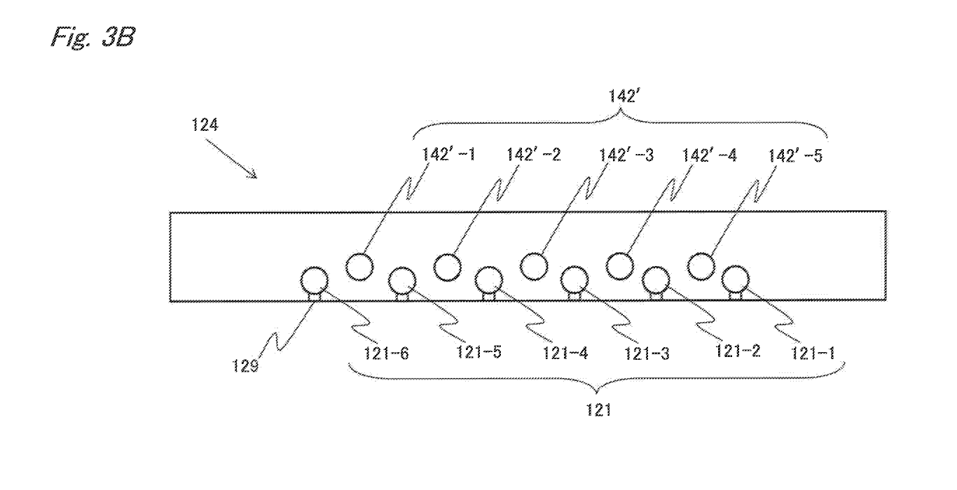

FIG. 3A is a schematic cross-sectional view along A-A′ line of FIG. 2.

FIG. 3B is a schematic view of another example of a shower plate of a film-forming apparatus according to the embodiment 1 of the present invention.

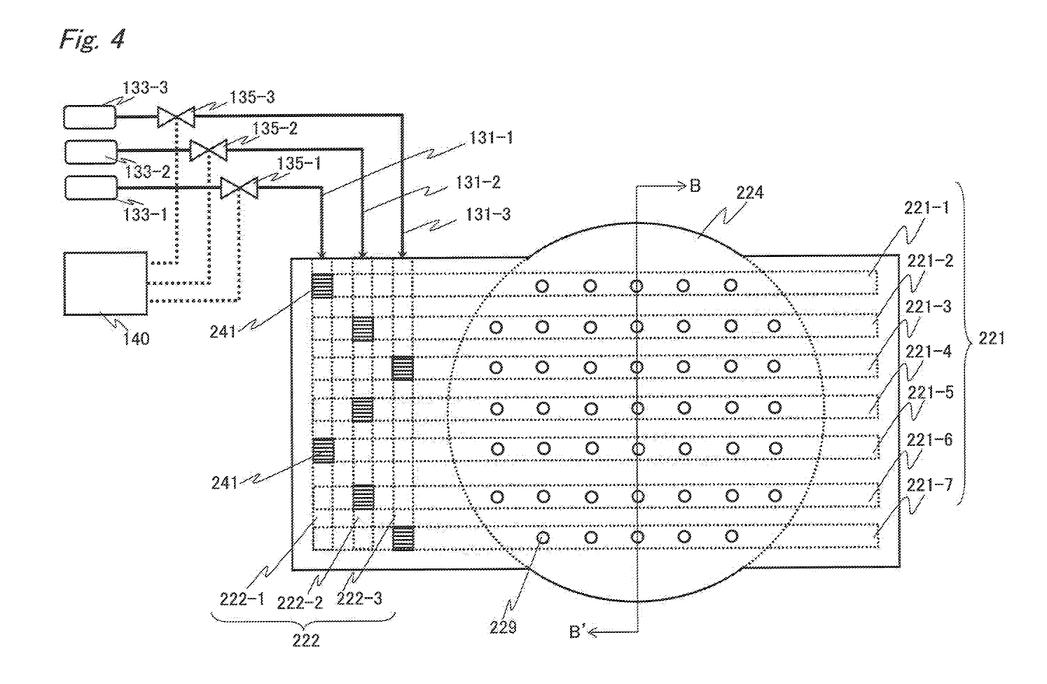

FIG. 4 is a schematic view of another example of a shower plate of a film-forming apparatus according to the embodiment 1 of the present invention.

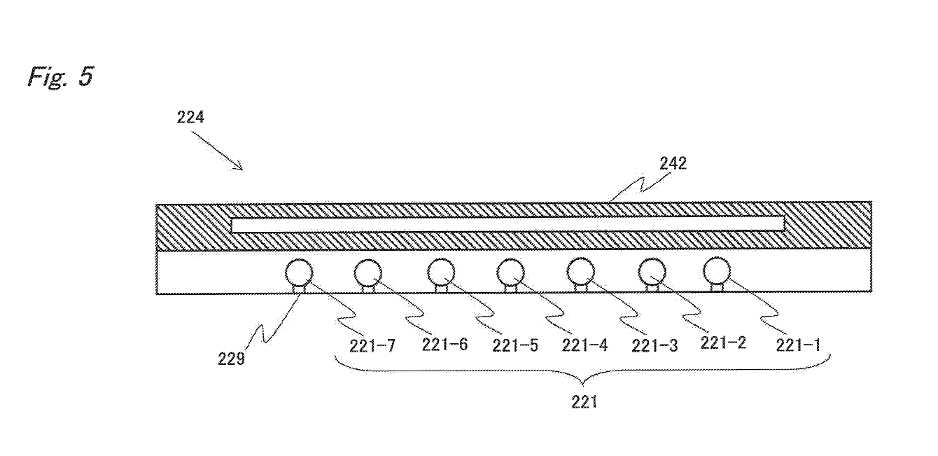

FIG. 5 is a schematic cross-sectional view along B-B′ line of FIG. 4.

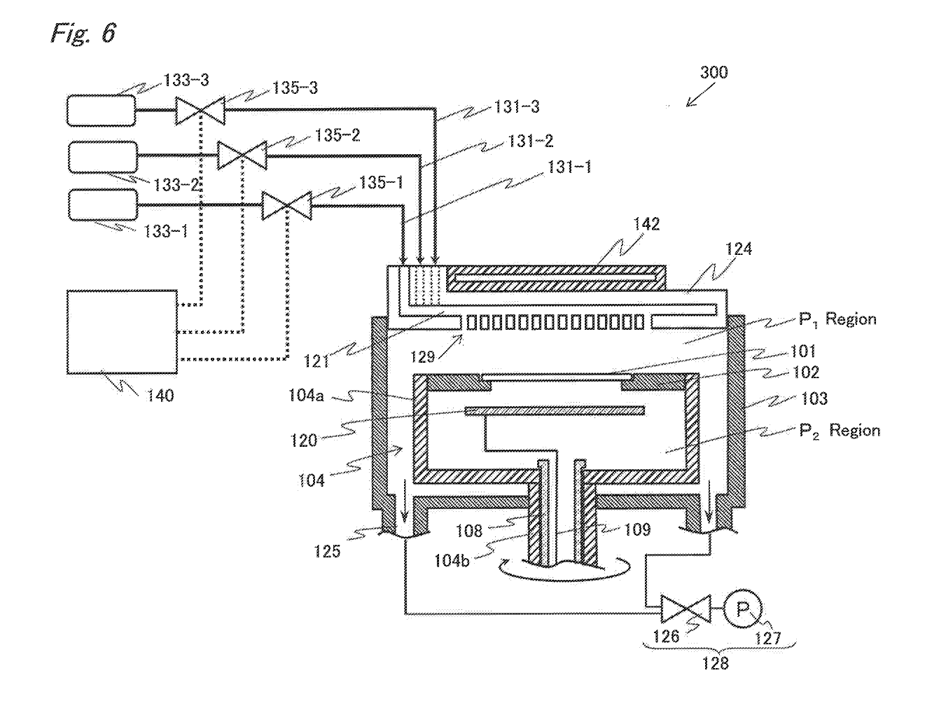

FIG. 6 is a schematic view of a single wafer film-forming apparatus according to the embodiment 2 of the present invention.

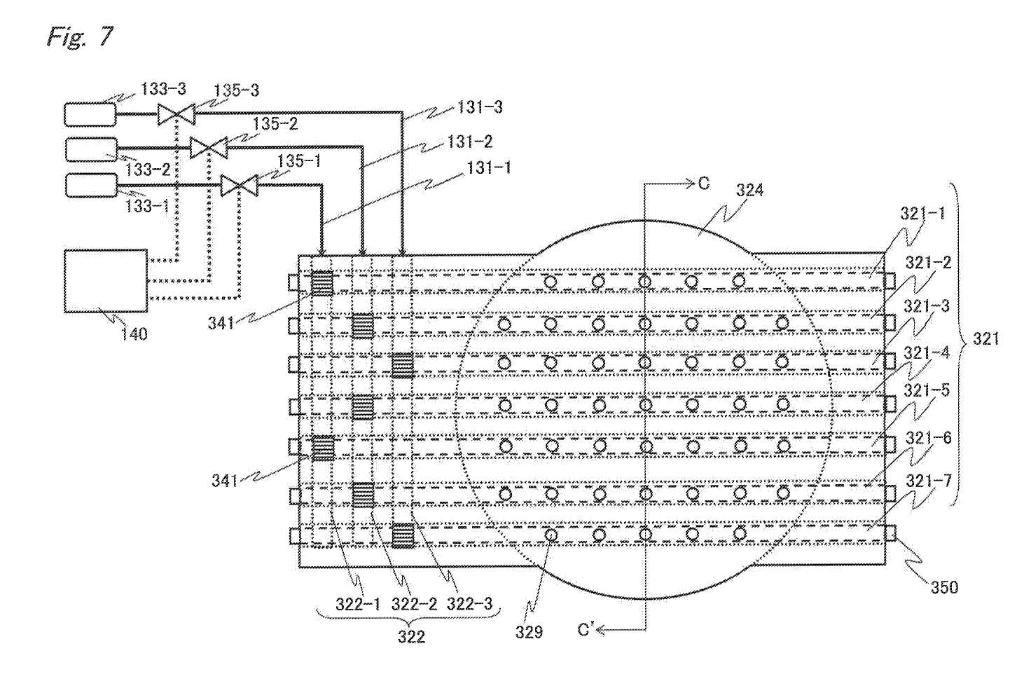

FIG. 7 is a schematic view of a shower plate of a film-forming apparatus according to the embodiment 3 of the present invention.

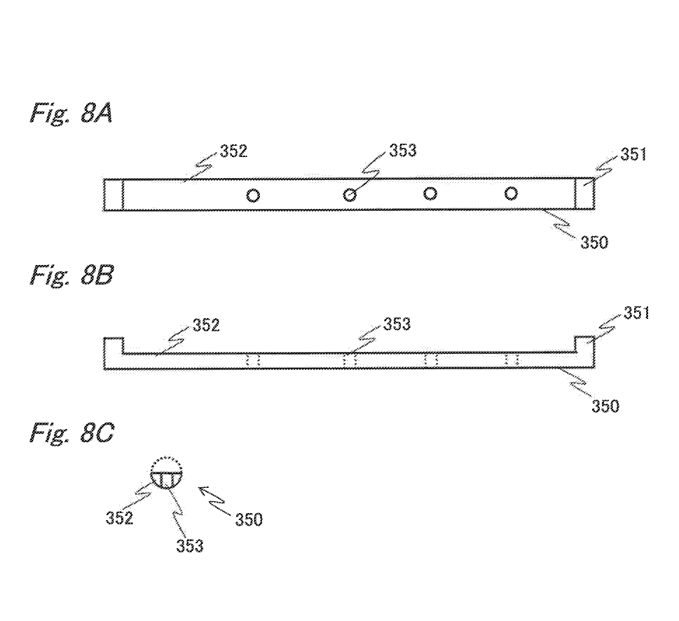

FIGS. 8A to 8C are views for explaining a structure of a rod-shaped member to be inserted into a gas flow path of a shower plate of this embodiment, FIG. 8A being a plan view of the rod-shaped member, FIG. 8B being a side view of the rod-shaped member, and FIG. 8C being a section of the rod-like member.

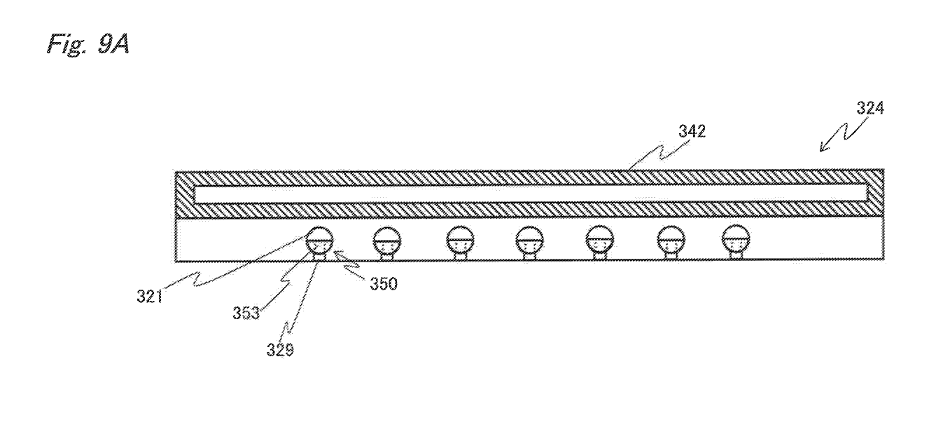

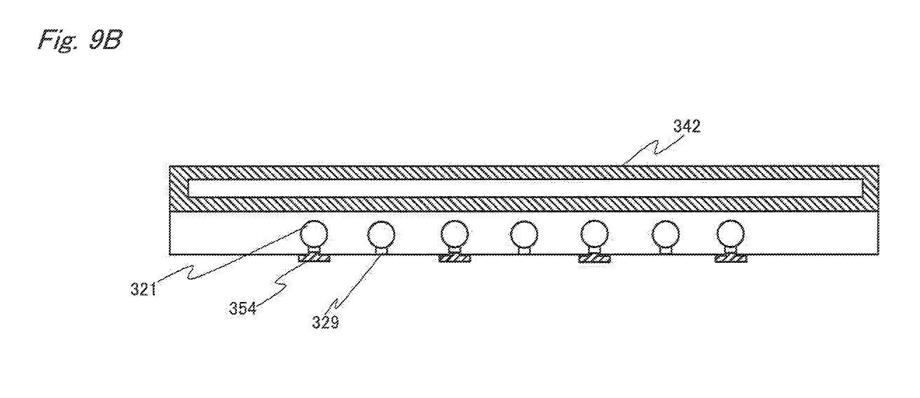

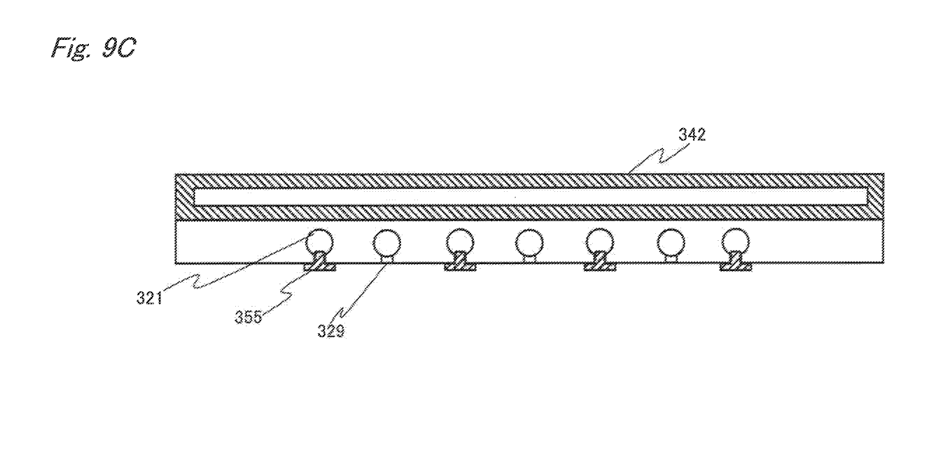

FIG. 9A is a schematic cross-sectional view of a shower plate of a film-forming apparatus according to the embodiment 3 of the present invention.

FIG. 9B is a schematic cross-sectional view of another example of a shower plate of a film-forming apparatus according to the embodiment 3 of the present invention.

FIG. 9C is a schematic cross-sectional view of another example of a shower plate of a film-forming apparatus according to the embodiment 3 of the present invention.

FIG. 10 is a schematic cross-sectional view of a conventional film-forming apparatus.

### DETAILED DESCRIPTION OF THE INVENTION

### Embodiment 1

FIG. 1 is a schematic view of a single wafer film-forming apparatus according to the embodiment 1 of the present invention.

The film-forming apparatus has a film-forming chamber in which a sample is disposed and a shower plate which supplies a plurality of gases toward the sample within the film-forming chamber. The shower plate is provided in an upper section of the film-forming chamber and the above gases are supplied to the film-forming chamber through the shower plate. Further, the shower plate has a first face directed to the inside of the film-forming chamber, a second face opposed to the first face and directed to the outside of the film-forming chamber, a plurality of gas flow paths extending along the first face and the second face therebetween, and a plurality of gas jetting holes causing the plurality of gas flow paths and the first face to communicate with each other, where gases supplied from respective one ends of the plurality of gas flow paths are jetted from the plurality of gas jetting holes toward the inside of the film-forming chamber. In other words, the shower plate has the plurality of gas flow paths extending therein along the first face directed to the side of the sample and connected to gas pipes supplying the respective plurality of gases, and a plurality of gas jetting holes bored so as to cause the respective plurality of gas flow paths and the inside of the film-forming chamber to communicate with each other on the side of the first face, where the respective gases of the plurality of gases supplied from the gas pipes to the plurality of gas flow paths are supplied from the plurality of gas jetting holes toward the sample, respectively.

Further, it is preferred that the film-forming apparatus has a gas supply control mechanism which controls a timing of supplying a first gas to at least one gas flow path of the plurality of gas flow paths and a timing of supplying a second gas to another gas flow path of the plurality of gas flow paths. In other words, it is preferred that the film-forming apparatus is provided with the gas supply control mechanism which supplies the respective plurality of gases to the gas pipes connected to the respective gas flow paths of the plurality of gas flow paths, and the gas supply control mechanism controls timings at which the respective plurality of gases are supplied to the gas pipes, respectively, and controls timings at which the respective plurality of gases are supplied toward the sample.

Furthermore, in the film-forming apparatus, it is preferred that the shower plate is provided with a colling mechanism on the side of the second face opposed to the first face on the side of the sample.

In FIG. 1, an outline of a configuration of a film-forming apparatus 100 of this embodiment will be described with an illustrative sectional view of a chamber 103 which is a film-forming chamber.

In this embodiment, a substrate 101 such as a wafer is used as a sample to be subjected to film-forming process. FIG. 1 shows a state where the substrate 101 has been placed on a susceptor 102 of the film-forming apparatus 100 of this embodiment. A film formation is performed by supplying a plurality of gases constituting raw materials for forming an epitaxial film to the substrate 101 placed on the susceptor 102 to cause vapor phase growth reaction on the substrate 101.

The film-forming apparatus 100 includes a chamber 103 to be used for forming an epitaxial film on the substrate 101 via vapor phase growth reaction.

A susceptor 102 is provided above the rotating portion 104 in the chamber 103. The susceptor 102 is a ring-shape with a counterbore provided within the opening so that the outer periphery of the substrate 101 can be positioned in the counterbore. As the susceptor 102 is used under high temperatures, a susceptor obtained by coating the surface of isotropic graphite with SiC, of a high degree of purity and a high resistance to heat, by CVD (Chemical Vapor Deposition) is used (as one example).

The shape of the susceptor 102 is not limited to the example of FIG. 1. For example, it is possible to configure the susceptor by providing a member for closing the opening portion.

The rotating portion 104 includes a cylindrical portion 104a and a rotating shaft 104b. The susceptor 102 is held above the cylindrical portion 104a in the rotating portion 104. A motor (not shown) rotates the rotating shaft 104b resulting in the susceptor 102 rotating via the cylindrical portion 104a. Accordingly the substrate 101 can be rotated after the substrate 101 is placed on the susceptor 102.

As seen in FIG. 1, the cylindrical portion 104a has an opening in the upper part of the portion. The susceptor 102 can be positioned in the opening, or on the opening of the cylindrical portion 104a, and then the substrate 101 is placed on the susceptor 102. This results in the opening being covered with the susceptor 102 and the substrate 101, and a hollow region (herein after P₂ region) is formed. Inside the chamber 103 the P₂ region is substantially separated from the P₁ region by the substrate 101 and the susceptor 102. Therefore, it is possible to prevent contamination of the substrate 101 by a contaminant generated around a heater 120 (described later). It is also possible to prevent the gas in the P₁ region, from coming into the P₂ region and contacting with the heater 120 provided in the P₂ region.

The heater 120 is provided in the P₂ region. For use as the heater 120, resistive heaters can be used; the material of these are obtained by coating the surface of carbon material with SiC of a high resistance to heat. Electricity is conducted to heater 120 via wires 109 positioned in a cylindrical shaped shaft 108, wherein the cylindrical shaped shaft 108 consists of quartz, contained in the rotating shaft 104b; thereby these heaters heat the back surface of the substrate 101 placed on the susceptor 102.

A pin (not shown), capable of moving in an up and down direction, supporting the substrate 101, is provided in the shaft 108. The end of the pin extends to a substrate elevating device (not shown) provided at the bottom of the shaft 108. The pin can be moved up and down by the substrate elevating device. The pin is used when the substrate 101 is transferred into and out of the chamber 103. The pin 101 supports the bottom of the substrate 101, and then rises to move the substrate 101 away from the susceptor 102. The substrate 101 is then positioned above the rotating portion 104 separate from the susceptor 102 by the pin, allowing a transfer robot (not shown) to remove the substrate 101.

A shower plate 124 is provided in an upper section of the chamber 103 of the film-forming apparatus 100. The shower plate 124 functions to rectify respective gases of the plurality of gases for forming an epitaxial film within the chamber 103 to supply them toward a surface of the substrate 101 in a shower fashion.

A plurality of gas discharge portions 125 for discharging a plurality of gases, are provided at the bottom of the chamber 103. The gas discharge portions 125 are connected to a discharge system 128 comprising an adjustment valve 126 and a vacuum pump 127. The discharge system 128 is controlled by a control system (not shown) to adjust the pressure in the chamber 103.

The shower plate 124 of the film-forming apparatus 100 will be described below in detail.

The shower plate 124 shown in FIG. 1 has a plate shape having a predetermined thickness. The shower plate 124 can be configured using a metal material such as stainless steel or aluminum alloy.

A plurality of gas flow paths 121 are provided inside the shower plate 124 along a face directed to the side of the substrate 101, which is a first face of the shower plate 124.

FIG. 2 is a schematic view of a shower plate of a film-forming apparatus according to the embodiment 1 of the present invention.

In FIG. 2, a structure and a function of the shower plate 124 will be described using an illustrative plan view of the shower plate 124 of this embodiment viewed from the side of the first face.

In the film-forming apparatus 100 of this embodiment, a plurality of gases can be used in order to form an epitaxial film. For example, three gases; a first, second, and a third gas can be used. The film-forming apparatus 100 introduces the first, second, and third gases into the chamber 103 using the shower plate 124 and rectifies these gases within the chamber 103 to supply the first, second, and third gases toward the surface of the substrate 101, respectively. Therefore, the shower plate 124 shown in FIG. 2 is configured so as to supply a first, second, and third gases to the substrate 101 within the chamber 103 in a state where they have been separated from one another without mixing these gases.

Incidentally, in the film-forming apparatus of this embodiment, the number of gases used for forming an epitaxial film is not limited to three, but it may be two or more than three. An example of the present invention using three gases will be described below.

The shower plate 124 shown in FIG. 2 includes six gas flow paths 121-1 to 121-6 provided therein as gas flow paths 121. The substrate 101 within the chamber 103 is disposed on the susceptor 102 horizontally. Therefore, it is preferred that the shower plate 124 is installed such that the first face of the shower plate 124 directed to the substrate 101 and opposed thereto becomes horizontal in the film-forming apparatus 100. In that case, it is preferred that the gas flow paths 121-1 to 121-6 inside the shower plate 124 are provided along the first face of the shower plate, and it is preferred that the respective gas flow paths extend horizontally in a state where the shower plate 124 has been installed. It is preferred that the gas flow paths 121-1 to 121-6 are arranged at predetermined intervals within the shower plate 124.

Incidentally, the shower plate 124 shown in FIG. 1 has six gas flow paths 121, but the number of gas flow paths 121 is not limited to six in the shower plate 124 of this embodiment. As described later, when three gases are used, if two gas flow paths 121 are caused to correspond to one gas, a total of six gas flow paths are provided. However, it is possible to cause more gas flow paths to correspond to one gas to provide more gas flow paths 121. Further, it is possible to cause different numbers of gas flow paths 121 to correspond to the respective gases of the plurality of gases used for forming an epitaxial film. That is, it is possible to increase or decrease the number of gas flow paths 121 to more numbers or less numbers.

The shower plate 124 of this embodiment has gas supply paths 122 at its end portion. The gas supply paths 122 are arranged so as to intersect with the respective gas flow paths 121-1 to 121-6. For example, as shown in FIG. 2, the gas supply paths 122 are arranged so as to form a matrix arrangement between them and the gas flow paths 121.

In FIG. 2, an example where three gas supply paths 122-1 to 122-3 have been provided as the gas supply paths 122 corresponding to the number of gases used.

Incidentally, in the shower plate 124 of this embodiment, it is preferred that the number of gas supply paths 122 is defined corresponding to the number of gases to be used, and the number of gas supply paths may be set to be equal to the number of gases.

The gas supply paths 122 are connected to gas pipes 131. That is, the gas supply paths 122-1 to 122-3 are connected to gas pipes 131-1, 131-2, and 131-3 at their end portions in a gas piping fashion. The gas pipes 131 are connected to gas supply sections 133 at their other ends. That is, the respective other ends of the gas pipes 131-1, 131-2, and 131-3 are connected to gas supply sections 133-1, 133-2, and 133-3 which are composed of bombs, respectively.

The gas pipes 131 include gas valves 135 in their intermediate portions. That is, gas valves 135-1, 135-2, and 135-3 which can adjust flow rates of gases to adjust supply amounts of gases are connected to the intermediate portions of the gas pipes 131-1 to 131-3, respectively. The gas valves 135-1 to 135-3 together with a gas control section 140 described later constitutes a gas supply control mechanism of the film-forming apparatus 100.

The film-forming apparatus 100 of this embodiment may be a film-forming apparatus which forms an SiC epitaxial film on a substrate 101. In that case, the first, second, and third gasses may be respectively a source gas for carbon, a separation gas, and a source gas for silicon. Here, in this embodiment, the separation gas is a gas used to separate the remaining two gases from each other, and it is a gas which is poor regarding its reactivity with the remaining two gases.

As the source gas for carbon which is the first gas, for example, a propane (C₃H₈) gas or a mixed gas of a propane gas and a hydrogen gas can be used. As the separation gas which is the second gas, a hydrogen (H₂) gas can be used. As the source gas for silicon which is the third gas, a silane (SiH₄) gas or a mixed gas of a silane gas and a hydrogen gas can be used.

Therefore, it is possible to set a gas supplied from the gas supply section 133-1 of the three gas supply sections 133 provided as the source gas for carbon which is the first gas. The source gas for carbon can be supplied to the gas pipe 131-1. Further, it is possible to set a gas supplied from the gas supply section 133-2 as the separation gas which is the second gas. The separation gas can be supplied to the gas pipe 131-2. Further, it is possible to set a gas supplied from the gas supply section 133-3 as the source gas for silicon which is the third gas. The source gas for silicon can be supplied to the gas pipe 131-3.

In that case, the source gas for carbon which is the first gas is supplied from the gas supply section 133-1 to the gas pipe 131-1 and further supplied to the gas supply path 122-1. The gas valve 135-1 of the gas pipe 131-1 functions to control the source gas for carbon which is the first gas. Similarly, the separation gas which is the second gas is supplied from the gas supply section 133-2 to the gas pipe 131-2 and further supplied to the gas supply path 122-2. The gas valve 135-2 of the gas pipe 131-2 functions to control the separation gas which is the second gas. Further, the source gas for silicon which is the third gas is supplied from the gas supply section 133-3 to the gas pipe 131-3 and further supplied to the gas supply path 122-3. The gas valve 135-3 of the gas pipe 131-3 functions to control the source gas for silicon which is the third gas.

The film-forming apparatus 100 has the gas control section 140. The gas control section 140 is connected to the gas valves 135-1 to 135-3, respectively. The gas control section 140 controls respective operations of the gas valves 135-1 to 135-3. The gas control section 140 controls supplies of the first, second, and third gases supplied from the gas supply sections 133-1 to 133-3 to the gas pipes 131-1 to 131-3. As a result, the gas control section 140 can control supplies of the respective gases of the first, second, and third gases described above from the gas pipes 131-1 to 131-3 to the gas supply paths 122-1 to 122-3. The gas control section 140 together with the gas valves 135-1 to 135-3 constitutes the gas supply control mechanism of the film-forming apparatus 100.

In the shower plate 124 of the film-forming apparatus 100, the three gas supply paths 122-1 to 122-3 intersect with the six gas flow paths 121-1 to 121-6, respectively, as shown in FIG. 2. The gas supply paths 122-1 to 122-3 constitute connection portions 141 at predetermined portions of the intersecting portions with the gas flow paths 121-1 to 121-6 to connect with the gas flow paths 121-1 to 121-6 in a gas piping fashion. Therefore, the gas flow paths 121-1 to 121-6 are connected to the gas pipes 131-1 to 131-3 via the connection portions 141 and corresponding gas supply paths 122-1 to 122-3.

At this time, in the shower plate 124, only predetermined some portions of all of the intersecting portions between the gas supply paths 122-1 to 122-3 and the gas flow paths 121-1 to 121-6 constitute the connection portions 141, but such a configuration is not adopted that the supply paths and the gas flow paths are connected to each other at all of the intersecting portions. In the shower plate 124, selection of the intersecting portions which perform gas piping connections to constitute the connection portions 141 is performed from the all the intersecting portions.

In the example shown in FIG. 2, for example, the intersecting portion between the gas supply path 122-1 and the gas flow path 121-1 is selected to constitute the connection portion 141. By configuring the connection portion 141, the gas supply path 122-1 and the gas flow path 121-1 are connected to each other in a gas piping fashion. As a result, the gas flow path 121-1 is connected to only the gas pipe 131-1 via the connection portion 141 and the gas supply path 122-1. The first gas supplied from the gas pipe 131-1 to the gas supply path 122-1 is supplied to the gas flow path 121-1 through the connection portion 141. That is, the gas flow path 121-1 constitutes a gas flow path for the first gas.

In the shower plate 124 shown in FIG. 2, similar intersecting portions 141 are constituted at the intersecting portions between the gas supply path 122-1 and the gas flow path 121-4, the intersecting portion between the gas supply path 122-2 and the gas flow path 121-2, the intersecting portion between the gas supply path 122-2 and the gas flow path 121-5, the intersecting portion between the gas supply path 122-3 and the gas flow path 121-3, and the intersecting portion between the gas supply path 122-3 and the gas flow path 121-6. As a result, the gas flow path 121-4 is connected to only the gas pipe 131-1 via the connection portion 141 and the gas supply path 122-1. The gas flow path 121-2 and the gas flow path 121-5 are connected to only the gas pipe 131-2 via the connection portions 141 and the gas supply path 122-2. The gas flow path 121-3 and the gas flow path 121-6 are connected to only the gas pipe 131-3 via the connection portions 141 and the gas supply path 122-3.

Therefore, the first gas supplied from the gas pipe 131-1 to the gas supply path 122-1 is supplied to the gas flow path 121-1 and the gas flow path 121-4 via the connection portions 141. The gas flow path 121-1 and the gas flow path 121-4 constitute gas flow paths for the first gas.

Similarly, the second gas supplied from the gas pipe 131-2 to the gas flow path 122-2 is supplied to the gas flow path 121-2 and the gas flow path 121-5 through the connection portions 141. The gas flow path 121-2 and the gas flow path 121-5 constitute gas flow paths for the second gas. Further, the third gas supplied from the gas pipe 131-3 to the gas supply path 122-3 is supplied to the gas flow path 121-3 and the gas flow path 121-6 through the connection portions 141. The gas flow path 121-3 and the gas flow path 121-6 constitute gas flow paths for the third gas.

Thus, in the shower plate 124, it is made possible to supply only one gas of the three gases to the respective six gas flow paths 121-1 to 121-6. That is, the shower plate 124 of this embodiment is constituted so as to select ones constituting the connection portion 141 from the plurality of intersecting portions between the gas flow paths 121-1 to 121-6 and the gas supply paths 122-1 to 122-3 properly to supply only one gas of the plurality of gases to the respective gas flow paths 121-1 to 121-6.

The shower plate 124 of this embodiment has a plurality of gas jetting holes 129 bored so as to cause the respective gas flow paths 121-1 to 121-6 and a P₁ region of the chamber 103 to communicate with each other on the side of the first face directed toward the side of the substrate 101. The gas jetting holes 129 are bored at respective arrangement positions of the gas flow paths 121-1 to 121-6, and they are arranged within the plane of the shower plate 124 in a distributed manner with predetermined distances among them.

Therefore, the first gas supplied from the gas pipe 131-1 to the gas flow path 121-1 and the gas flow path 121-4 through the gas supply path 122-1 and the connection portions 141 is jetted from the gas jetting holes 129 bored at the arrangement positions of the gas flow path 121-1 and the gas flow path 121-4 to be supplied toward the substrate 101.

Similarly, the second gas supplied from the gas pipe 131-2 to the gas flow path 121-2 and the gas flow path 121-5 through the gas supply path 122-2 and the connection portions 141 is jetted from the gas jetting holes 129 bored at the arrangement positions of the gas flow path 121-2 and the gas flow path 121-5 to be supplied toward the substrate 101. Further, the third gas supplied from the gas pipe 131-3 to the gas flow path 121-3 and the gas flow path 121-6 through the gas flow path 122-3 and the connection portions 141 is jetted from the gas jetting holes 129 bored at the arrangement positions of the gas flow path 121-3 and the gas flow path 121-6 to be supplied toward the substrate 101. Thus, in the shower plate 124 of this embodiment, the three gases are supplied toward the substrate 101 in a shower fashion in their separated state without being mixed with one another.

As described above, the film-forming apparatus 100 of this embodiment has the gas supply control mechanism composed of the gas control section 140 and the gas valves 135-1 to 135-3.

Therefore, using the gas supply control mechanism, the film-forming apparatus 100 can supply the respective first, second, and third gases to the respective gas flow paths 121-1 to 121-6 connected to the gas pipes 131-1 to 131-3 and simultaneously can jet the three gases which have been separated from one another from the gas jetting holes 129 to be supplied toward the substrate 101 in a shower fashion.

Even in such a case, the gas flow paths 121-1 to 121-6 for supplying the first, second, and third gases are independent from one another, and it is inhibited in the shower plate 124 that these gases are mixed and react among them.

Further, using the gas supply control mechanism, the film-forming apparatus 100 can control timings and terms of supplying the first, second, and third gases to the gas flow paths 121-1 to 121-6 connected with the gas pipes 131-1 to 131-3. The film-forming apparatus 100 can control timings of supplying of the first, second, and third gases from the gas jetting holes 129 toward the substrate 101.

As a result, the source gas for carbon which is the first gas and the source gas for silicon which is the third gas, these source gases easily reacting with each other, can be prevented from being simultaneously jetted from the gas jetting holes 129. That is, the term of jetting the source gas for carbon which is the first gas from the gas jetting holes 129 and the term of jetting the source gas for silicon which is the third gas from gas jetting holes 129 can be separated from each other so that the former gas and the latter gas can be supplied toward the substrate 101 in a time-divisional fashion, respectively. As a result, these gases can be inhibited from being mixed on the surface of or in the vicinity of the shower plate 124 to react between each other.

Further, using the gas supply control mechanism, the film-forming apparatus 100 can supply the respective first, second, and third gases to the respective gas pipes 131-1 to 131-3 in the time-divisional fashion, respectively, to supply these gases to the respective gas flow paths 121-1 to 121-6 connected to the gas pipes 131-1 to 131-3. As a result, only one gas of the first, second, and third gases can be jetted from only predetermined gas jetting holes 129 of the gas jetting holes 129 of the shower plate 124 in a predetermined term. Thereafter, the remaining gases can be sequentially jetted from only corresponding predetermined gas jetting holes 129 in predetermined terms, respectively. As a result, these gases can be inhibited from being mixed on the surface of or in the vicinity of the shower plate 124 to react between each other.

Further, using the gas supply control mechanism, it is made possible to set the term of supplying the separation gas which is the second gas toward the substrate 101 after the first gas is supplied toward the substrate 101 and set a supply term of the second gas after the third gas is supplied. That is, it is possible to set the term of supplying only hydrogen gas which is the separation gas necessarily after the source gas for carbon is supplied and after the source gas for silicon is supplied. By adopting such a configuration, the source gas for carbon and the source gas for silicon are inhibited from being mixed to react between each other further effectively on the surface of or in the vicinity of the shower plate 124.

Next, as shown in FIG. 1, the shower plate 124 of the film-forming apparatus 100 can includes a colling mechanism on the side of the second face opposed to the first face formed with the gas jetting holes 129 and directed to the side of the substrate 101.

As the colling mechanism of the shower plate 124 of this embodiment, a hollow flow path 142 through which a coolant such as a cooling water passes can be provided.

FIG. 3A is a schematic cross-sectional view along A-A′ line of FIG. 2.

As shown in FIG. 3, the flow path 142 of the shower plate 124 is configured such that inside thereof is hollow. The flow path 124 is configured such that the coolant such as cooling water passing through the inside spreads in a plane shape on the side of the second face of the shower plate 124.

By providing the flow path 142 with such a structure, cooling is made possible in the shower plate 124 and the shower plate 124 is inhibited to reach a high temperature.

Further, as shown in FIG. 3B, a flow path 142′ of the shower plate 124 may be provided internally on the side of the first face of the shower plate 124. It is preferred that a plurality of flow paths 142′ is provided such as 142′-1, 142′-2, 142′-3, and 142′-4.

By providing the flow paths 142′ having such a structure, cooling inside the shower plate 124 is made possible and the shower plate 124 is inhibited from reaching a high-temperature state.

As a result, a plurality of gases constituting raw materials for forming an epitaxial film can be inhibited from thermally reacting inside the shower plate 124 or in the vicinity thereof. Consequently, such a problem that a film is formed inside the shower plate 124 or the surface thereof can be inhibited.

As described above, in the film-forming apparatus 100 of this embodiment, a plurality of gases can be used in order to form an epitaxial film, but the example shown in FIG. 1 to FIG. 3 is configured to use first, second, and third gases. As described above, the number of gases which can be used in the film-forming apparatus of this embodiment is not limited to three. For example, the number of kinds may be two, and it may be more than three.

In that case, it is preferred that the number of the gas supply paths 122 of the shower plate 124, such as shown in FIG. 2, is changed corresponding to the number of gases used for formation of an epitaxial film. In addition, it is preferred that the numbers of the gas pipes 131, the gas valves 135, and the gas supply sections 133 are also caused to correspond to the number of gases.

For example, when the number of gases to be used is four (for example, H₂, SiH₄, C₃H₈, and N₂), four gas supply paths similar to the gas supply path 122 shown in FIG. 2 are provided at an end portion of the shower plate. It is preferred that four gas pipes, four gas valves, and four gas supply sections connected to the four gas supply paths and similar to the gas pipe 131, the gas valve 135, and the gas supply section 133 shown in FIG. 2 are provided, respectively.

By adopting such a configuration, four gases are supplied to the inside of the chamber without being mixed in the shower plate, that is, a first, second, third, and fourth gas. It is possible to inhibit these gases from reacting at the shower plate to form an epitaxial film on a substrate.

Further, when the number of gases to be used is five (for example, H₂, SiH₄, C₃H₈, N₂, and TMA), five gas supply paths similar to the gas supply path 122 shown in FIG. 2 are provided at an end portion of the shower plate. It is preferred that five gas pipes, five gas valves, and five gas supply sections connected to the five gas supply paths and similar to the gas pipe 131, the gas valve 135, and the gas supply section 133 shown in FIG. 2 are provided, respectively.

Next, in this embodiment, it is possible to use, as the shower plate of the film-forming apparatus, another shower plate which is different in number of gas flow paths and arrangement structure from the shower plate shown in FIG. 2 to configure another example of the film-forming apparatus. As described below, by adopting such another shower plate, spatial separation between the source gas for carbon which is the first gas and the source gas for silicon which is the second gas, which are jetted from the gas jetting holes, can be performed further effectively.

Incidentally, even in the other example of the film-forming apparatus of this embodiment, a plurality of gases can be used in order to form an epitaxial film like the above-described film-forming apparatus 100, but an example configured to use a first, second, and third gas will be described herein.

FIG. 4 is a schematic view of another example of a shower plate of a film-forming apparatus according to the embodiment 1 of the present invention.

The other example of the film-forming apparatus of this embodiment has, as the shower plate, a shower plate 224 shown in FIG. 4.

The shower plate 224 shown in FIG. 4 has a plate shape having a predetermined thickness. The shower plate 224 can be made of metal material such as stainless steel or aluminum alloy.

The shower plate 224 has a structure similar to that of the shower plate 124 of the first embodiment shown in FIG. 2 except that the former is different in number of gas flow paths 221 and arrangement structure from the latter. Further, the other example of the film-forming apparatus of the first embodiment having the shower plate 224 has a structure similar to that of the film-forming apparatus 100 shown in FIG. 1. Therefore, same constituent elements as those in the first embodiment are attached with same reference numerals, and repetitive explanation thereof is omitted.

Seven gas flow paths 221 are provided inside the shower plate 224 so as to extend along a face directed to the side of the substrate 101, which is a first face of the shower plate 224. It is preferred that the shower plate 224 is installed such that the first face of the shower plate 224 directed to the side of the substrate 101 and opposed thereto becomes horizontal. It is preferred that the gas flow paths 221-1 to 221-7 inside the shower plate 224 are formed to extend horizontally inside the shower plate 224 in a state that the shower plate has been installed in the other example of the film-forming apparatus, and it is also preferred that the gas flow paths 221-1 to 221-7 are arranged at predetermined intervals.

The shower plate 224 has three gas supply paths 222 at its end portion. The gas supply paths 222 are arranged so as to intersect with the gas flow paths 221-1 to 221-7, respectively. For example, as shown in FIG. 4, the gas supply paths 222 are arranged in a matrix fashion between them and the gas flow paths 221.

The gas supply paths 222-1 to 221-3 are connected to the gas pipes 131-1, 131-2, and 131-3 at their end portions in gas piping fashion, respectively. The other ends of the gas pipes 131-1, 131-2, and 131-3 are connected to the gas supply sections 133-1, 133-2, and 133-3 composed of bombs, respectively.

Gas valves 135-1, 135-2, and 135-3 which can adjust gas flow rates to adjust supply amounts of gases are connected to middle portions of the gas pipes 131-1 to 131-3. The gas valves 135-1 to 135-3 together with a gas control section 140 described later constitutes a gas supply control mechanism of the film-forming apparatus 100.

The other example of the film-forming apparatus of the first embodiment can form an SiC epitaxial film on a substrate 101 like the film-forming apparatus 100. In that case, the first, second, and third gases may be a source gas for carbon, a separation gas, and a source gas for silicon. The separation gas is a gas for separating the source gas for carbon and the source gas for silicon from each other, as described above.

In that case, the source gas for carbon which is the first gas is supplied from the gas supply section 133-1 to the gas pipe 131-1 and further supplied to the gas supply path 222-1. Similarly, the separation gas which is the second gas is supplied from the gas supply section 133-2 to the gas pipe 131-2 and further supplied to the gas supply path 222-2. Further, the source gas for silicon which is the third gas is supplied from the gas supply section 133-3 to the gas pipe 131-3 and further supplied to the gas supply path 222-3.

In the shower plate 224 of the other example of the film-forming apparatus, as shown in FIG. 4, the three gas supply paths 222-1 to 222-3 intersect with the seven gas flow paths 221-1 to 221-7, respectively. The gas supply paths 222-1 to 222-3 constitutes connection portions 241 at predetermined some portions of the intersecting portions with the gas flow paths 221-1 to 221-7 to achieve gas piping connection with corresponding gas flow paths 221-1 to 221-7. Therefore, the gas flow paths 221-1 to 221-7 are connected to corresponding gas pipes 131-1 to 131-3 via the connection portions 241 and the gas supply paths 222-1 to 222-3.

In the example shown in FIG. 4, for example, the connection portion 241 is constituted at the intersecting portion between the gas supply path 222-1 and the gas flow path 221-1. By constituting the connection portion 241, the gas supply path 222-1 and the gas flow path 221-1 are connected to each other in a gas piping fashion. As a result, the gas flow path 221-1 is connected to only the gas pipe 131-1 via the connection portion 241 and the gas supply path 222-1. The first gas supplied from the gas pipe 131-1 to the gas supply path 222-1 is supplied to the gas flow path 221-1 via through the connection portion 241. That is, the gas flow path 22-1 constitutes a gas flow path for the first gas.

In the shower plate 224 shown in FIG. 4, similar connection portions 241 are constituted at the intersecting portion between the gas supply path 222-1 and the gas flow path 221-5, the intersecting portion between the gas supply path 222-2 and the gas flow path 221-2, the intersecting portion between the gas supply path 222-2 and the gas flow path 221-4, the intersecting portion between the gas supply path 222-2 and the gas flow path 221-6, the intersecting portion between the gas supply path 222-3 and the gas flow path 221-3, and the intersecting portion between the gas supply path 222-3 and the gas flow path 221-7. As a result, the gas flow path 221-5 is connected to only the gas pipe 131-1 via the connection portion 241 and the gas supply path 222-1. The gas flow path 221-2, the gas flow path 221-4, and the gas flow path 221-6 are connected to only the gas pipe 131-2 via the connection portions 241 and the gas supply path 222-2. The gas flow path 221-3 and the gas flow path 221-7 are connected to only the gas pipe 131-3 via the connection portions 241 and the gas supply path 222-3.

Therefore, the first gas supplied from the gas pipe 131-1 to the gas supply path 222-1 is supplied to the gas flow path 221-1 and the gas flow path 221-5 through the connection portions 241. The gas flow path 221-1 and the gas flow path 221-5 are gas flow paths for the first gas.

Similarly, the second gas supplied from the gas pipe 131-2 to the gas supply path 222-2 is supplied to the gas flow path 221-2, the gas flow path 221-4, and the gas flow path 221-6 via the connection portions 241. The gas supply path 221-2, the gas supply path 221-4, and the gas supply path 221-6 constitute gas flow paths for the second gas. Further, the third gas supplied from the gas pipe 131-3 to the gas supply path 222-3 is supplied to the gas flow path 221-3 and the gas flow path 221-7 through the connection portions 241. The gas flow path 221-3 and the gas flow path 221-7 constitute gas flow path for the third gas.

Thus, the shower plate 224 can supply only one gas of the first, second, and third gases to the respective seven gas flow paths 221-1 to 221-7. That is, the shower plate 224 is configured to select ones constituting the connection portions 241 from the plurality of intersecting portions between the gas flow paths 221-1 to 221-7 and the gas supply paths 222-1 to 222-3 properly to supply only one gas of the plurality of gases to the gas flow paths 221-1 to 221-7, respectively.

The shower plate 224 has a plurality of gas jetting holes 229 bored such that the respective gas flow paths 221-1 to 221-7 and a P₁ region of the chamber 103 communicate with each other on the side of the first face directed to the side of the substrate 101. The gas jetting holes 229 are bored at arrangement positions of the gas flow paths 221-1 to 221-7, and are configured such that they are disposed within a plane of the shower plate 224 at predetermined intervals from each other in a distributed fashion.

Therefore, the first gas supplied from the gas pipe 131-1 to the gas flow path 221-1 and the gas flow path 221-5 through the gas supply path 222-1 and the connection portions 241 is jetted from the gas jetting holes 229 bored at the arrangement positions of the gas flow path 221-1 and the gas flow path 221-5 to be supplied toward the substrate 101. Similarly, the second gas supplied from the gas pipe 131-2 to the gas flow path 221-2, the gas flow path 221-4, and the gas flow path 221-6 through the gas supply path 222-2 and the connection portions 241 is jetted from the gas jetting holes 229 bored at the arrangement positions of the gas flow path 221-2, the gas flow path 221-4, and the gas flow path 221-6 to be supplied to toward the substrate 101. Further, the third gas supplied from the gas pipe 131-3 to the gas flow path 221-3 and the gas flow path 221-7 through the gas supply path 222-3 and the connection portions 241 is jetted from the gas jetting holes 229 bored at the arrangement positions of the gas flow path 221-3 and the gas flow path 221-7 to be supplied toward the substrate 101. Thus, in the shower plate 224 of this embodiment, the respective first, second, and third gases are supplied toward the substrate 101 in a shower fashion, respectively.

At this time, the shower plate 224 has a structure where the gas flow paths 221-2, 221-4, and 221-6 are arranged between the gas flow paths 221-1 and 221-5 to which the first gas is supplied and the gas flow paths 221-3 and 221-7 to which the third gas is supplied. As described above, the first gas is the source gas for carbon and the third gas is the source gas for silicon, so that these gases easily react between each other. Therefore, in the shower plate 224, the gas flow paths for two gases which easily react between each other are arranged in a spatially-separated state and the gas flow path for the second gas (separation gas) which is poor in reactivity is arranged between the gas flow paths.

As a result, the first gas and the third gas jetted from the gas jetting holes 229 of the shower plate 224 are separated from each other spatially and the spatial separation is made further effective by a spatial separation effect due to jetting of the separation gas which is the second gas.

In the other example of the film-forming apparatus of the first embodiment, a gas supply control mechanism composed of the gas control section 140 and the gas valves 135-1 to 135-3 is provided like the above-described film-forming apparatus 100.

Therefore, the other example of the film-forming apparatus of the first embodiment can control timings and terms of supplying the respective first, second, and third gases to the respective gas flow paths 221-1 to 221-7 connected to the gas pipes 131-1 to 131-3 using the gas supply control mechanism. The gas supply control mechanism can control timings of supplying the respective first, second, and third gases from the gas jetting holes 229 toward the substrate 101 like the above-described film-forming apparatus 100.

That is, it is possible to perform such setting that only one gas of the first, second, and third gases is jetted for a predetermined period from only predetermined gas jetting holes 229 of the gas jetting holes 229 of the shower plate 224. It is possible to perform such setting that the other gases are thereafter sequentially jetted for predetermined periods from only corresponding predetermined gas jetting holes 229. As a result, these gases are inhibited from being mixed to react between each another on the surface of or in the vicinity of the shower plate 224.

Incidentally, the shower plate 224 can have a colling mechanism colling mechanism on the side of a second face formed with the gas jetting holes 229 and opposed to the first face directed to the side of the substrate 101 like the shower plate 124 of the film-forming apparatus 100 shown in FIG. 1.

As the colling mechanism of the shower plate 224 of this embodiment, a hollow flow path 242 through which a coolant such as cooling water passes can be provided.

FIG. 5 is a schematic cross-sectional view along B-B′ line of FIG. 4.

As shown in FIG. 5, the flow path 242 of the shower plate 224 is configured to be hollow therein. The flow path 242 is configured such that the coolant such as cooling water passing through the flow path 242 spreads in a plane fashion on the side of the second face of the shower plate 224.

By providing the flow path 242 having such a structure, cooling is made possible in the shower plate 224 and the shower plate 124 is inhibited from reaching a high temperature. As a result, a plurality of gases constituting raw materials for forming an epitaxial film is inhibited from thermally reacting within the shower plate 224. As a result, such a problem can be inhibited that a film is formed inside or on the surface of the shower plate 224.

As described above, the other example of the film-forming apparatus of the first embodiment can separate the source gas for carbon and the source gas for silicon which can easily react between each other further effectively using the shower plate 224 to jet them from the gas jetting holes 229 toward the substrate 101. It is possible to conduct cooling using the flow path 242 of the coolant in the shower plate 224.

### Embodiment 2

According to the present invention, a film-forming apparatus is provided using a metal organic chemical vapor deposition method (MOCVD method).

A film-forming apparatus for forming a GaN epitaxial film on the substrate using MOCVD method according to the embodiment 2 of the present invention is mentioned as follows.

The film-forming apparatus has a film-forming chamber in which a sample is disposed and a shower plate which supplies a plurality of gases toward the sample within the film-forming chamber. The shower plate is provided in an upper section of the film-forming chamber and the above gases are supplied to the film-forming chamber through the shower plate. Further, the shower plate has a first face directed to the inside of the film-forming chamber, a second face opposed to the first face and directed to the outside of the film-forming chamber, a plurality of gas flow paths extending along the first face and the second face therebetween, and a plurality of gas jetting holes causing the plurality of gas flow paths and the first face to communicate with each other, where gases supplied from respective one ends of the plurality of gas flow paths are jetted from the plurality of gas jetting holes toward the inside of the film-forming chamber. In other words, the shower plate has the plurality of gas flow paths extending therein along the first face directed to the side of the sample and connected to gas pipes supplying the respective plurality of gases, and a plurality of gas jetting holes bored so as to cause the respective plurality of gas flow paths and the inside of the film-forming chamber to communicate with each other on the side of the first face, where the respective gases of the plurality of gases supplied from the gas pipes to the plurality of gas flow paths are supplied from the plurality of gas jetting holes toward the sample, respectively.

Further, it is preferred that the film-forming apparatus has a gas supply control mechanism which controls a timing of supplying a first gas to at least one gas flow path of the plurality of gas flow paths and a timing of supplying a second gas to another gas flow path of the plurality of gas flow paths. In other words, it is preferred that the film-forming apparatus is provided with the gas supply control mechanism which supplies the respective plurality of gases to the gas pipes connected to the respective gas flow paths of the plurality of gas flow paths, and the gas supply control mechanism controls timings at which the respective plurality of gases are supplied to the gas pipes, respectively, and controls timings at which the respective plurality of gases are supplied toward the sample.

Furthermore, in the film-forming apparatus, it is preferred that the shower plate is provided with a colling mechanism on the side of the second face opposed to the first face on the side of the sample.

The film-forming apparatus of the second embodiment, as gases used for formation of a GaN epitaxial film, can use, for example, a first, second, and third gas, that is, a source gas for nitrogen (N) such as ammonia (NH₃), a separation gas such as hydrogen gas, and a source gas for gallium (Ga) such as trimethyl gallium (TMG). Here, the separation gas is a gas for separating the source gas for nitrogen such as ammonia and the source gas for gallium such as trimethyl gallium from each other, and it is a gas which is poor in reactivity with them. That is, the film-forming apparatus of the second embodiment uses a first, second, and third gas constituting raw materials for forming an epitaxial film on a substrate.

The structure of the film-forming apparatus of the second embodiment may be similar to that of the above-described film-forming apparatus 100 of the first embodiment. Therefore, in the film-forming apparatus of the second embodiment, same constituent elements as those of the film-forming apparatus 100 of the first embodiment are attached with same reference numerals in the first embodiment and repetitive explanation is omitted.

FIG. 6 is a schematic view of a single wafer film-forming apparatus according to the embodiment 2 of the present invention.

In FIG. 6, an outline of a configuration of a film-forming apparatus 300 of this embodiment will be described with reference to an illustrative sectional view of a chamber 103 which is a film-forming chamber.

In the film-forming apparatus 300 of the second embodiment, it is possible to define a gas supplied from a gas supply section 133-1 of three gas supply sections 133 provided as a first gas and set a source gas for nitrogen (N) such as, for example, ammonia (NH₃) as the first gas. The source gas for nitrogen can be supplied to a gas pipe 131-1.

Further, it is possible to define a gas supplied from a gas supply section 133-2 as a second gas and set a separation gas such as, for example, hydrogen gas as the second gas. The separation gas can be supplied to a gas pipe 131-2. Further, it is possible to define a gas supplied from a gas supply section 133-3 as a third gas and set a source gas for gallium such as, for example, trimethyl gallium (TMG) gas as the third gas. The source gas for gallium can be supplied to a gas pipe 131-3.

The film-forming apparatus 300 is provided with a shower plate 124 similar to that in the film-forming apparatus 100 shown in FIG. 2. Therefore, the shower plate 124 of the film-forming apparatus 300 can supply only one of the first, second, and third gases to respective six gas flow paths 121-1 to 121-6.

Therefore, in the film-forming apparatus 300, the first gas supplied from the gas pipe 131-1 to the gas flow path 121-1 and the gas flow path 121-4 via the gas supply path 122-1 and the connection portions 141 is jetted from the gas jetting holes 129 bored at the arrangement positions of the gas flow path 121-1 and the gas flow path 121-4 to be supplied toward a substrate 101. Similarly, the second gas supplied from the gas pipe 131-2 to the gas flow path 121-2 and the gas flow path 121-5 through the gas supply path 122-2 and the connection portions 141 is jetted from the gas jetting holes 129 bored at the arrangement positions of the gas flow path 121-2 and the gas flow path 121-5 to be supplied to the substrate 101. Further, the third gas supplied from the gas pipe 131-3 to the gas flow path 121-3 and the gas flow path 121-6 through the gas supply path 122-3 and the connection portions 141 is jetted from the gas jetting holes 129 bored at the arrangement positions of the gas flow path 121-3 and the gas flow path 121-6 to be supplied toward the substrate 101. Thus, in the shower plate 124 of the film-forming apparatus 300, the respective first, second, and third gases are supplied toward the substrate 101 in a shower fashion.

The film-forming apparatus 300 of this embodiment has a gas supply control mechanism composed of a gas control section 140 and gas valves 135-1 to 135-3.

Therefore, the film-forming apparatus 300 can supply the first, second, and third gases to the respective gas flow paths 121-1 to 121-6 connected to the gas pipes 131-1 to 131-3 using the gas supply control mechanism and simultaneously can jet the respective gases from the gas jetting holes 129 bored at the arrangement positions of the gas flow paths 121-1 to 121-6 to supply them toward the substrate 101 in a shower fashion.

Even in that case, the gas flow paths 121-1 to 121-6 for supplying the respective first, second, and third gases are independent from one another, and these gases are inhibited from being mixed to react between each other in the shower plate 124.

Further, the film-forming apparatus 300 can control timings and terms of supplying the first, second, and third gases to the respective gas flow paths 121-1 to 121-6 connected to the gas pipes 131-1 to 131-3 using the gas supply control mechanism. The film-forming apparatus 300 can control timings of supplying the respective first, second, and third gases from predetermined gas jetting holes 129 toward the substrate 101.

As a result, the source gas for nitrogen which is the first gas and the source gas for gallium which is the third gas which easily reacts between each other can be prevented from being simultaneously jetted from the gas jetting holes 129. That is, by separating the term of jetting the source gas for nitrogen which is the first gas from predetermined gas jetting holes 129 and the term of jetting the source gas for gallium which is the third gas from other predetermined gas jetting holes 129, the respective source gases can be supplied toward the substrate 101 in a time-divisional manner. As a result, the source gas for nitrogen and the source gas for gallium can be inhibited from being mixed to react between each other on the surface of or in the vicinity of the shower plate 124.

Further, the film-forming apparatus 300 can supply the respective gases to the respective gas pipes 131-1 to 131-3 in a time-divisional manner to supply them to the gas flow paths 121-1 to 121-6 connected to the gas pipes 131-1 to 131-3 using the gas supply control mechanism. As a result, only one gas can be jetted from predetermined gas jetting holes 129 of the shower plate 124 for a predetermined term. Thereafter, the other gases can be sequentially jetted from predetermined gas jetting holes 129 for predetermined terms, respectively. As a result, the source gas for nitrogen and the source gas for gallium are inhibited from being mixed to react between each other on the surface of or in the vicinity of the shower plate 124.

Further, using the gas supply control mechanism, it is possible to provide a term of supplying the second gas (separation gas) toward the substrate 101 after supplying the first gas toward the substrate 101 and provide a term of supplying the second gas (separation gas) after supplying the third gas toward the substrate 101. That is, it is possible to provide a term of supplying only hydrogen gas which is the separation gas necessarily after supplying the source gas for nitrogen and supplying the source gas for gallium. By adopting such a configuration, the source gas for nitrogen and the source gas for gallium can be inhibited from being mixed to react between each other on the surface of or in the vicinity of the shower plate 124 further effectively.

Further, the film-forming apparatus 300 can be provided with a shower plate having a structure similar to that of the shower plate 224 shown in FIG. 4 as the shower plate.

In that case, the shower plate 224 of the film-forming apparatus 300 can supply only one gas of the first, second, and third gases to the respective seven gas flow paths 221-1 to 221-7.

Therefore, the first gas supplied from the gas pipe 131-1 to the gas flow path 221-1 and the gas flow path 221-5 through the gas supply path 222-1 and the connection portions 241 is jetted from the gas jetting holes 229 bored at the arrangement positions of the gas flow path 221-1 and the gas flow path 221-5 to be supplied toward the substrate 101. Similarly, the second gas supplied from the gas pipe 131-2 to the gas flow path 221-2, the gas flow path 221-4, and the gas flow path 221-6 through the gas supply path 222-2 and the connection portions 241 is jetted from the gas jetting holes 229 bored at the arrangement positions of the gas flow path 221-2, the gas flow path 221-4, and the gas flow path 221-6 to be supplied toward the substrate 101. Further, the third gas supplied from the gas pipe 131-3 to the gas flow path 221-3 and the gas flow path 221-7 through the gas supply path 222-3 and the connection portions 241 is jetted from the gas jetting holes 229 bored at the arrangement positions of the gas flow path 221-3 and the gas flow path 221-7 to be supplied toward the substrate 101. Thus, in the shower plate 224 of this embodiment, the respective gases are supplied toward the substrate 101 in a shower fashion.

At this time, the shower plate 224 has such a structure that the gas flow paths 221-2, 221-4, and 221-6 to which the second gas is supplied are arranged between the gas flow paths 221-1 and 221-5 to which the first gas is supplied and the gas flow paths 221-3 and 221-7 to which the third gas is supplied. As described above, the first gas is the source gas for nitrogen and the third gas is the source gas for gallium, so that both the gases easily react between each other. Therefore, in the shower plate 224, the flow paths for the respective two gases which easily react between each other are arranged in a spatially-separated manner, and the flow path for the second gas which is poor in reactivity is arranged between these flow paths.

As a result, the first gas and the third gas jetted from the gas jetting holes 229 bored at the arrangement positions of the respective gas flow paths 221-1 to 221-7 of the shower plate 224 are separated from each other spatially and the spatial separation is made further effective by the separation effect obtained by jetting the second gas.

The film-forming apparatus 300 can control timings and terms of supplying the respective first, second, and third gases to the respective gas flow paths 221-1 to 221-7 connected with the gas pipes 131-1 to 131-3 using the above-described gas supply control mechanism. The film-forming apparatus 300 can control timings of supplying the respective gases from the gas jetting holes 229 toward the substrate 101 like the film-forming apparatus 100.

That is, only one gas of the first, second, and third gases can be jetted from only predetermined gas jetting holes 229 of the shower plate 224 for a predetermined term. Thereafter, the other gases can be sequentially jetted from only corresponding predetermined gas jetting holes 229 for predetermined terms, respectively. As a result, these gases can be inhibited from being mixed to react between each other on the surface of or in the vicinity of the shower plate 224.

From the above, using the shower plate 224, the film-forming apparatus 300 can separate the source gas for nitrogen and the source gas for gallium which easily react between each other from each other spatially and temporally further effectively to be jetted from the gas jetting holes 229. As a result, these gases can be inhibited from being mixed to thermally react between each other on the surface of or in the vicinity of the shower plate 224.

### Embodiment 3

A film-forming apparatus of a third embodiment has a film-forming chamber in which a sample is disposed and a shower plate which supplies a plurality of gases toward the sample within the film-forming chamber. The shower plate is provided in an upper section of the film-forming chamber and the above gases are supplied to the film-forming chamber through the shower plate. Further, the shower plate has a first face directed to the inside of the film-forming chamber, a second face opposed to the first face and directed to the outside of the film-forming chamber, a plurality of gas flow paths extending along the first face and the second face therebetween, and a plurality of gas jetting holes causing the plurality of gas flow paths and the first face to communicate with each other, where gases supplied from respective one ends of the plurality of gas flow paths are jetted from the plurality of gas jetting holes toward the inside of the film-forming chamber. In other words, the shower plate has the plurality of gas flow paths extending therein along the first face directed to the side of the sample and connected to gas pipes supplying the respective plurality of gases, and a plurality of gas jetting holes bored so as to cause the respective plurality of gas flow paths and the inside of the film-forming chamber to communicate with each other on the side of the first face, where the respective gases of the plurality of gases supplied from the gas pipes to the plurality of gas flow paths are supplied from the plurality of gas jetting holes toward the sample, respectively.

Further, it is preferred that the film-forming apparatus has a gas supply control mechanism which controls a timing of supplying a first gas to at least one gas flow path of the plurality of gas flow paths and a timing of supplying a second gas to another gas flow path of the plurality of gas flow paths. In other words, it is preferred that the film-forming apparatus is provided with the gas supply control mechanism which supplies the respective plurality of gases to the gas pipes connected to the respective gas flow paths of the plurality of gas flow paths, and the gas supply control mechanism controls timings at which the respective plurality of gases are supplied to the gas pipes, respectively, and controls timings at which the respective plurality of gases are supplied toward the sample.

Furthermore, in the film-forming apparatus, it is preferred that the shower plate is provided with a colling mechanism on the side of the second face opposed to the first face on the side of the sample.

Furthermore, the shower plate is configured such that each of the gas flow paths extends through the shower plate in a predetermined direction along the first face, it is provided with a rod-shaped member inserted into each of the gas flow paths, the rod-shaped member closes at least some of the plurality of gas jetting holes causing the gas flow path which has been inserted with the rod-shaped member and the film-forming chamber to communicate with each other and has through-holes formed so as to causing the remaining gas jetting holes and the gas flow path to communicate with each other, and it is preferred that the shower plate is configured such that at least a portion of each gas supplied to each of the gas flow paths is supplied from the gas jetting holes communicating with the through-holes of the rod-shaped member toward the sample through the through-holes of the rod-shaped member.

As described above, the film-forming apparatus 100 of the first embodiment and the film-forming apparatus 300 of the second embodiment can have the shower plate 124 and the shower plate 224. The shower plate 124 or 224 have the plurality of gas jetting holes 129 or 229 bored so as to cause the gas flow paths 121 or 221 and the P₁ region of the chamber 103 to communicate with each other on the side of the first face directed to the side of the substrate 101. The plurality of gases constituting the raw materials for forming the epitaxial film on the substrate 101 are supplied from the gas jetting holes 129 or 229 toward the substrate 101. At this time, selection of the gas jetting holes 129 or 229 used to jet the respective first, second, and third gases constituting the raw materials and the amounts of the gases jetted from the respective gas jetting holes 129 or 229 can be controlled by the gas supply control mechanism composed of the gas control section 140 and the gas valves 135-1 to 135-3.

In that case, in the film-forming apparatuses 100 or 300, control by the gas supply control mechanism is performed for each of the gas flow paths 121-1 to 121-6, or 221-1 to 221-7. Therefore, control to jetting gas is performed for the plurality of gas jetting holes 129 or 229 bored at the respective arrangement positions of the gas flow paths 121-1 to 121-6 or 221-1 to 221-7. It is impossible to select some gas jetting holes of the plurality of gas jetting holes 129 or 229 bored corresponding to one arrangement position of the arrangement positions of the gas flow paths 121-1 to 121-6 or 221-1 to 221-7 to stop jetting of a predetermined gas or adjust the supply amount. Therefore, in the shower plates 124 or 224, it is difficult to control the distributions of the gas jetting holes 129 or 229 jetting the respective plurality of gases finely as desired.

Therefore, the film-forming apparatus which is the third embodiment of the present invention is configured such that gas jetting holes to be used to jet each gas of the plurality of gases can be selected further finely in the shower plate. The shower plate is configured such that the distribution of the gas jetting holes jetting each gas of the plurality of gases can be controlled further finely.

FIG. 7 is a schematic view of a shower plate of a film-forming apparatus according to the embodiment 3 of the present invention.

The film-forming apparatus which is the third embodiment of the present invention is configured to have a shower plate 324 shown in FIG. 7. The film-forming apparatus according to the third embodiment has the same structure as those of the above-described film-forming apparatus 100 and the like except for a difference in structure of the gas flow paths 321 which are constituent elements of the shower plate 324. Therefore, same constituent elements as those in the film-forming apparatus 100 and the like are attached with same reference numerals and repetitive explanation thereof is omitted.

As shown in FIG. 7, the shower plate 324 of the film-forming apparatus of the third embodiment has a plate shape having a predetermined thickness. The shower plate 324 can be configured using a metal material such as stainless steel or aluminum alloy.

Seven gas flow paths 321 are provided within the shower plate 324 so as to extend along a face directed to the side of a substrate 101, which is a first face of the shower plate 324. It is preferred that the shower plate 324 is installed such that the first face of the shower plate 324 directed to the side of the substrate 101 and opposed thereto becomes horizontal. Gas flow paths 321-1 to 321-7 within the shower plate 324 extend horizontally in a state where the shower plate 324 has been installed and they are formed in a tunnel shape extending through the shower plate 324 in a horizontal direction. The gas flow paths 321-1 to 321-7 are arranged at predetermined intervals inside the shower plate 324.

It is preferred that the gas flow path 321 extending through the shower plate 324 in the horizontal direction is formed in a shape having a circular section. The shower plate 324 has a rod-shaped member 350 inserted into the gas flow path 321.

As described in detail later, the rod-shaped member 350 has a shape where a main body 352 thereof other than distal end portions at both ends thereof has a semi-circular section, and spaces where the respective plurality of gases flow are secured within the gas flow paths 321-1 to 321-7.

The shower plate 324 has three gas supply paths 322 at its end portion. The gas supply paths 322 are arranged so as to intersect with the respective gas flow paths 321-1 to 321-7.

The gas supply paths 322-1 to 322-3 are connected to gas pipes 131-1, 131-2, and 131-2 at their end portions in a gas-piping manner, respectively. The other ends of the gas pipes 131-1, 131-2, and 131-3 are connected to respective gas supply sections 133-1, 133-2, and 133-3 constituted by using bombs.

Gas valves 135-1, 135-2, and 135-3 which can adjust flow rates of gases to adjust supply amounts of gases are connected to the intermediate portions of the gas pipes 131-1 to 131-3, respectively. The gas valves 135-1 to 135-3 together with a gas control section 140 described later constitute a gas supply control mechanism of the film-forming apparatus of the third embodiment.

The film-forming apparatus of the third embodiment can form an SiC epitaxial film on a substrate 101. In that case, the three gases may be a source gas for carbon, a separation gas, and a source gas for silicon. As described above, the separation gas is a gas for separating the source gas for carbon and the source gas for silicon from each other.

In that case, the source gas for carbon which is the first gas is supplied from the gas supply section 133-1 to the gas pipe 131-1 and further supplied to the gas supply path 322-1. Similarly, the separation gas which is the second gas is supplied from the gas supply section 133-2 to the gas pipe 131-2 and further supplied to the gas supply path 322-2. Further, the source gas for silicon which is the third gas is supplied from the gas supply section 133-3 to the gas pipe 131-3 and further supplied to the gas supply path 322-3.

In the shower plate 324 of the gas-forming apparatus of the third embodiment, as shown in FIG. 7, three gas supply paths 322-1 to 322-3 intersect with the seven gas flow paths 321-1 to 321-7, respectively. The gas supply paths 322-1 to 322-3 constitute connection portions 341 at predetermined portions of the intersecting portions with the gas flow paths 321-1 to 321-7 to connect with corresponding gas flow paths 321-1 to 321-7 in a gas piping fashion. Therefore, the gas flow paths 321-1 to 321-7 are connected to corresponding gas pipes 131-1 to 131-3 via the connection portions 341 and the gas supply paths 322-1 to 322-3.

In the example shown in FIG. 7, for example, the connection portion 341 is constituted at the intersecting portion between the gas supply path 322-1 and the gas flow path 321-1. By constituting the connection portion 341, the gas supply path 322-1 and the gas flow path 321-1 are connected to each other in a gas-piping fashion. As a result, the gas flow path 321-1 is connected to the gas pipe 131-1 via the connection portion 341 and the gas supply path 322-1. The first gas supplied from the gas pipe 131-1 to the gas supply path 322-1 is supplied to the gas flow path 321-1 through the connection portion 341. That is, the gas flow path 321-1 constitutes a gas flow path for the first gas.

In the shower plate 324 shown in FIG. 7, similar connection portions 341 are constituted at an intersecting portion between the gas supply path 322-1 and the gas flow path 321-5, an intersecting portion between the gas supply path 322-2 and the gas flow path 321-2, an intersecting portion between the gas supply path 322-2 and the gas flow path 321-4, an intersecting portion between the gas supply path 322-2 and the gas flow path 321-6, an intersecting portion between the gas supply path 322-3 and the gas flow path 321-3, and an intersecting portion between the gas supply path 322-3 and the gas flow path 321-7. As a result, the gas flow path 321-5 is connected to the gas pipe 131-1 via the connection portion 341 and the gas supply path 322-1. The gas flow path 321-2, the gas flow path 321-4, and the gas flow path 321-6 are connected to the gas pipe 131-2 via the connection portions 341 and the gas supply path 322-2. The gas flow path 321-3 and the gas flow path 321-7 are connected to the gas pipe 131-3 via the connection portions 341 and the gas supply path 322-3.

Therefore, the first gas supplied from the gas pipe 131-1 to the gas supply path 322-1 is supplied to the gas flow path 321-1 and the gas flow path 321-5 through the connection portions 341. The gas flow path 321-1 and the gas flow path 321-5 constitute gas flow paths for the first gas.

Similarly, the second gas supplied from the gas pipe 131-2 to the gas supply path 322-2 is supplied to the gas flow path 321-2, the gas flow path 321-4, and the gas flow path 321-6 through the connection portions 341. The gas flow path 321-2, the gas flow path 321-4, and the gas flow path 321-6 constitute gas flow paths for the second gas. Further, the third gas supplied from the gas pipe 131-3 to the gas supply path 322-3 is supplied to the gas flow path 321-3 and the gas flow path 321-7 through the connection portions 341. The gas flow path 321-3 and the gas flow path 321-7 constitute gas flow path for the third gas.

Thus, the shower plate 324 can supply only one gas of the first, second, and third gases to the respective seven gas flow paths 321-1 to 321-7. That is, the shower plate 324 is configured so as to select, from the plurality of intersecting portions between the gas flow paths 321-1 to 321-7 and the gas supply paths 322-1 to 322-3, ones constituting the connection portion properly and supply only one gas of the plurality of gases to the respective gas flow paths 321-1 to 321-7.

The shower plate 324 has a plurality of gas jetting holes 329 bored so as to cause the respective gas flow paths 321-1 to 321-7 and the P₁ region of the chamber 103 to communicate with each other on the side of the first face directed to the side of the substrate 101. The gas jetting holes 329 are bored at the arrangement positions of the gas flow paths 321-1 to 321-7 and they are configured to be arranged within a plane of the shower plate 324 with predetermined intervals from each other in a distributed manner.

Therefore, the first gas supplied from the gas pipe 131-1 to the gas flow path 321-1 and the gas flow path 321-5 via the gas supply path 322-1 and the connection portions 341 is controlled by the rod-shaped members 350 described in detail later to be jetted from the gas jetting holes 329 and supplied toward the substrate 101. Similarly, the second gas supplied from the gas pipe 131-2 to the gas flow path 321-2, the gas flow path 321-4, and the gas flow path 321-6 through the gas supply path 322-2 and the connection portions 341 is controlled by the rod-shaped members 350 to be jetted from the gas jetting holes 329 and supplied toward the substrate 101. Further, the third gas supplied from the gas pipe 131-3 to the gas flow path 321-3 and the gas flow path 321-7 through the gas supply path 322-3 and the connection portions 341 is controlled by the rod-shaped members 350 to be jetted from the gas jetting holes 329 and supplied toward the substrate 101. Thus, in the shower plate 324 of this embodiment, the respective gases are supplied toward the substrate 101 in a shower fashion.

At this time, the shower plate 324 has such a structure that the gas flow path 321-2, 321-4, or 321-6 to which the second gas (separation gas) is supplied is arranged between the gas flow path 321-1 or 321-5 to which the first gas is supplied and the gas flow path 321-3 or 321-7 to which the third gas is supplied. As described above, the first gas is the source gas for carbon and the third gas is the source gas for silicon, where both the gases easily react between each other. Therefore, in the shower plate 324, the flow paths for the respective two gases which easily react between each other are arranged so as to be separated from each other spatially and the flow path for the second gas (separation gas) which is poor in reactivity is disposed between both the flow paths.

As a result, the first gas and the third gas jetted from the gas jetting holes 329 of the shower plate 324 are separated from each other spatially and the spatial separation is made further effective by the separation effect due to jetting of the second gas.

The film-forming apparatus of the third embodiment has a gas supply control mechanism composed of the gas control section 140 and the gas valves 135-1 to 135-3 like the film-forming apparatus 100 described above.

Therefore, the film-forming apparatus of the third embodiment can control timings and terms of supplying the first, second, and third gases to the respective gas flow paths 321-1 to 321-7 connected to the gas pipes 131-1 to 131-3 using the gas supply control mechanism. The film-forming apparatus 300 can control timings of supplying the respective gases from the gas jetting holes 329 toward the substrate 101 like the film-forming apparatus 100.

That is, only one gas of the first, second, and third gases is jetted from only predetermined gas jetting holes 329 of the shower plate 324 for a predetermined term. Thereafter, the other gases can be sequentially jetted from only corresponding predetermined gas jetting holes 329 for predetermined terms, respectively. As a result, these gases are inhibited from being mixed to react between each other on the surface of or in the vicinity of the shower plate 324.

As described above, the shower plate 324 of the film-forming apparatus of the third embodiment is provided with the rod-shaped members 350 inserted into the gas flow paths 321, and the structure and the function of the rod-shaped member 350 will be described in detail below.

FIGS. 8A to 8C are views for explaining a structure of a rod-shaped member to be inserted into a gas flow path of a shower plate of this embodiment, FIG. 8A being a plan view of the rod-shaped member, FIG. 8B being a side view of the rod-shaped member, and FIG. 8C being a section of the rod-like member.

A rod-shaped member 350 shown in FIGS. 8A to 8C has a length corresponding to the length of the gas flow path 321. The rod-shaped member 350 has distal end portions 351 having a predetermined length at both ends thereof. The distal end portions 351 have circular sectional shapes, respectively. In the rod-shaped member 350, its main body 352 other than the distal end portions 351 at both the ends is provided with a semi-circular sectional shape. Incidentally, regarding the length of the rod-shaped member 350, it is possible to make the length equal to the length of the gas flow path 321, but it is also possible to make the rod-shaped member 350 slightly longer than the gas flow path 321 such that portions of the distal end portions 351 project from the gas flow path 321 in a state that the rod-shaped member 350 has been inserted in the gas flow path 321.

The rod-shaped member 350 is formed such that a radius of the section of the distal end portion 351 having the circular section and a radius of the section of the main body 352 having the semicircular section are substantially equal to a radius of the section of the gas flow path 321. Therefore, when the rod-shaped member 350 is inserted into the gas flow path 321, both the distal end portions 351 of the rod-shaped member 350 close the gas flow path 321 from both ends thereof. Therefore, when the rod-shaped members 350 are inserted in the gas flow paths 321 and installed at proper positions, the respective plurality of gases supplied to the gas flow paths 321 are prevented from flowing out of both ends of the gas flow paths 321.

At this time, the main body 352 of the rod-shaped member 350 has a semicircular sectional shape. Therefore, a space is formed between the gas flow path 321 and the main body 352 of the rod-shaped member 350 within the gas flow path 321, so that a flow path for each gas of the plurality of gases is secured.

FIGS. 9A to 9C is a schematic cross-sectional view of a shower plate of a film-forming apparatus according to the embodiment 3 of the present invention.

As shown in FIGS. 8A to 8C and FIG. 9A, the main body 352 functions to close the gas jetting holes 329 causing the gas flow path 321 and the P₁ region of the chamber 103 to communicate with each other in a state where the rod-shaped member 350 has been inserted in the gas flow path 321. On the other hand, the main body 352 is formed with through-holes 353 extending through the main body 352 vertically.

The through-holes 353 of the main body 352 constitute a flow path for each gas of the plurality of gases in a state where the rod-shaped member 350 has been inserted in the gas flow path 321.

The rod-shaped member 350 which has been inserted in the gas flow path 321 causes the through-holes 353 of the main body 352 and the gas jetting holes 329 of the shower plate 324 to communicate with each other and allows gas supplied in the gas flow path 321 to be jetted from the gas jetting holes 329.

Thus, in the shower plate 324, the rod-shaped member 350 is inserted in the gas flow path 321 to function to close some of the plurality of gas jetting holes 329 causing the gas flow path 321 and the inside of the chamber 103 to communicate with each other. In addition, the rod-shaped member 350 causes the remaining gas jetting holes 329 and the gas flow path 321 to communicate with each other through the through-holes 353 to be capable of supplying each gas of the plurality of gases supplied to the gas flow path 321 from the gas jetting holes 329 communicating with the through-holes 353 toward the substrate 101 at least partially.

Here, in the film-forming apparatus which is the third embodiment, the through-holes 353 of the main body 352 of the rod-shaped member 350 can be formed to have a desired arrangement structure. For example, the through-holes 353 can be formed in the main body 352 to have a formation pitch of two times a formation pitch of the gas jetting holes 329 of the shower plate 324.

When the rod-shaped member 350 provided with such an arrangement structure of the through-holes 353 has been inserted into the gas flow path 321, half of gas jetting holes 329 of the gas jetting holes 329 bored at the arrangement positions of the gas flow path 321 are closed. That is, the gas jetting holes 329 existing at positions corresponding to the through-holes 353 of the main body 352 are not closed by the main body 352. Only the gas jetting holes 329 which do not exist at the positions corresponding to the through-holes 353 are closed by the main body 352 of the rod-shaped member 350. As a result, half of the gas jetting holes 329 bored at the arrangement positions of the gas flow paths 321 and jetting each gas of a plurality of gases are closed such that the plurality of gas jetting holes 329 actually arranged are alternatively closed, and the remaining gas jetting holes are used for gas jetting.

Thus, by control performed by the rod-shaped member 350 having a desired arrangement structure of the through-holes 353, it is made possible to select, from the plurality of gas jetting holes 329 which have been already bored, ones to be used actually. That is, some of a plurality of gas jetting holes 329 bored at the arrangement position of each of the gas flow paths 321-1 to 321-7 so as to correspond to each of the gas flow paths 321-1 to 321-7 can be closed by the rod-shaped member 350. By adopting such a configuration, it is made possible to perform selection of gas jetting holes 329 to be used from the plurality of gas jetting holes 329 to jet a predetermined gas toward the substrate 101.

Further, it is possible to provide the through-holes 353 of the main body 352 of the rod-shaped member 350 only in the vicinity of a central portion thereof selectively without providing in portions of the main body 352 near both the end portions thereof. In that case, gas jetting holes separated from the central portion of the main body 352 are selected from the plurality of gas jetting holes 329 bored at the arrangement position of the gas flow path 321 and closed by the main body 352 of the rod-shaped member 350. As the gas jetting holes 329 which can jet each gas, gas jetting holes 329 positioned in the vicinity of the central portion of the main body 352 are selected so that gas jetting is concentrated at the central portion. As a result, in the film-forming apparatus of the third embodiment, a predetermined gas can be supplied from the shower plate 324 to be concentrated to the central portion of the substrate 101.

On the contrary, it is possible to provide through-holes 353 to be formed in the main body 352 of the rod-shaped member 350 at portions thereof near both the end portions of the main body 352 selectively without providing the through-holes 353 in the central portion of the main body 352. In that case, gas jetting holes at a position near the central portion of the main body 352 are selected from the plurality of gas jetting holes 329 bored in the arrangement position of the gas flow path 321 and are closed by the main body 352 of the rod-shaped member 350. As the gas jetting holes 329 which can jet each gas, gas jetting holes 329 positioned near the end portions of the main body 352 except for the central portion of the main body 352 are selected. As a result, in the film-forming apparatus of the third embodiment, a predetermined gas can be supplied from the shower plate 324 toward a peripheral edge portion of the substrate 101.

Incidentally, the closing member for closing the gas jetting holes 329 is not limited to the rod-shaped member 350 and it is possible to close the gas jetting holes 329 selectively using lids 354 or screws 355, as shown in FIG. 9B and FIG. 9C.

As described above, the film-forming apparatus which is the third embodiment of the present invention can inhibit a plurality of gases used from being mixed to thermally react between them on the surface of or in the vicinity of the shower plate 324. Further, the shower plate 324 is configured such that the gas jetting holes 329 for jetting each gas of the plurality of gases can be selected by controlling the arrangement structure of the through-holes of the rod-shaped member 350 to be inserted into the gas flow path 321. As a result, in the shower plate 324, a distribution of the gas jetting holes 329 for jetting each of the plurality of gases can be controlled further finely as desired.

The fourth embodiment is a film-forming method for supplying a plurality of gases from a shower plate toward a sample disposed in a film-forming chamber to form a predetermined film on the sample, where the shower plate has a plurality of gas flow paths extending within the shower plate along a first face directed to the side of the sample, and a plurality of gas jetting holes bored such that the respective plurality of gas flow paths communicate with the inside of the film-forming chamber on the side of the first face, where gas pipes which supply the plurality of gases, respectively, are connected to the plurality of gas flow paths, respectively, and the plurality of gases are supplied from the respective gas pipes to the plurality of gas flow paths to be jetted from the gas jetting holes toward the sample, respectively.

Here, a method for forming an SiC epitaxial film on a substrate will be described as an example. The film-forming method of this embodiment can be implemented using the other example of the film-forming apparatus 100 of the first embodiment shown in FIG. 1, which is the film-forming apparatus of the embodiment of the present invention having the shower plate 224 shown in FIG. 4. Therefore, explanation is made while referring to the figures such as FIG. 1, FIG. 4, and FIG. 5 appropriately.

In the film-forming method according to the present embodiment, an epitaxial film is formed on the substrate 101 by vapor phase growth reaction. During the film-forming process, it is possible to prevent a plurality of gases mixing, thereby preventing these gases producing a heat reaction on and around the surface of the shower plate 224. The diameter of the substrate 101 is 200 mm or 300 mm for example.

The substrate 101 is transferred into the chamber 103 of the film-forming apparatus 100 by a transfer robot (not shown).

A pin (not shown) capable of moving in an up and down direction supporting the substrate 101, is provided through the rotating shaft 104b in the rotating portion 104 of the film-forming apparatus 100 as shown in FIG. 1. The substrate 101 is transferred to the pin from the transfer robot.

The pin rises from the first position to a predetermined position above the susceptor 102 to receive the substrate 101 from the transfer robot, after the substrate 101 is transferred to the pin; the pin descends while holding the substrate 101.

The pin is returned to the first position. Thereby the substrate 101 is positioned on the susceptor 102 on the cylindrical portion 104a of the rotating portion 104.

Next, the pressure of the chamber 103 is set to a specific atmospheric pressure or a reduced pressure, and then a gas valve 135-2 is controlled by a gas control section 140. Thereby a hydrogen gas as the separation gas which is the second gas, is supplied from the gas supply portion 123 to the gas pipe 131-2 by the gas control section 140. Then the hydrogen gas is supplied to the gas flow paths 221-2, 221-4, 221-6 through the gas flow path 222-2 and the connection portion 241. Then the hydrogen gas is jetted from the gas jetting holes 229, thereby the hydrogen gas is supplied to the P₁ region. The substrate 101 is rotates at about 50 rpm via the rotating portion 104 while the hydrogen gas is flows.

Next, the substrate 101 is heated to between 1100 and 1200 degrees by the heater 120. For example, the substrate 101 would be gradually heated to 1150 degrees as a film-forming temperature. At the same time, cooling water is supplied into the path 242 of the shower plate 224, thereby starting cooling of the shower plate 224.

After it is confirmed that the temperature of the substrate 101 reached 1650° C., the number of revolutions of the substrate 101 positioned on the susceptor 102 is gradually increased. Then the gas valves 135-1 to 135-3 are controlled by the gas control section 140. Then first, second, and third gases are supplied from the respective gas supply sections 133-1, 133-2, and 133-3 to the respective gas pipes 131-1 to 131-3. Thereby the first gas, the second gas and the third gas are supplied to the P1 region in the chamber 103.

While the temperature of the substrate 101 is maintained at 1650 degrees, and the susceptor 102 on the cylindrical portion 104a is rotating at 900 rpm or more, the speed of the vapor phase growth reaction process on the substrate 101 is increased, and then the epitaxial film can be efficiently formed at high speed.

Three gases for forming the SiC epitaxial film on the substrate 101 are a source gas for carbon, a separation gas, and a source gas for silicon. As the source gas for carbon which is the first gas, a mixed gas of propane and hydrogen gas is used. As the separation gas which is the second gas, hydrogen (H₂) gas is used. As the source gas for silicon which is the third gas, a mixed gas of silane gas and hydrogen gas is used.

The mixed gas of propane and hydrogen gas, which is the first gas, is supplied from the gas supply section 133-1 to the gas pipe 131-1 and further supplied to the gas supply path 222-1 under the control of the gas control section 140. Similarly, the hydrogen gas which is the second gas is supplied from the gas supply section 133-2 to the gas pipe 131-2 and further supplied to the gas supply path 222-2. Further, the mixed gas of silane gas and hydrogen gas, which is the third gas, is supplied from the gas supply section 133-3 to the gas pipe 131-3 and further supplied to the gas supply path 222-3.

Next, the mixed gas of propane and hydrogen gas which has been supplied to the gas supply path 222-1 is supplied to the gas flow path 221-1 and the gas flow path 221-5 through the connection portions 241.

Similarly, the hydrogen gas which has been supplied to the gas supply path 222-2 is supplied to the gas flow path 221-2, the gas flow path 221-4, and the gas flow path 221-6 through the connection portions 241. Further, the mixed gas of silane gas and hydrogen gas which has been supplied to the gas flow path 222-3 is supplied to the gas flow path 221-3 and the gas flow path 221-7 through the connection portions 241.

Thus, in the shower plate 224, only one gas of three gases is supplied to respective seven gas flow paths 221-1 to 221-7.

The shower plate 224 has a plurality of gas jetting holes 229 bored such that the respective gas flow paths 221-1 to 221-7 and the P₁ region of the chamber 103 communicate with each other on the side of the first face directed to the side of the substrate 101.

Therefore, the mixed gas of propane gas and hydrogen gas, which has been supplied to the gas flow path 221-1 and the gas flow path 221-5 is jetted from the gas jetting holes 229 bored at the arrangement positions of the gas flow path 221-1 and the gas flow path 221-5 to be supplied toward the substrate 101. Similarly, the hydrogen gas which has been supplied to the gas flow path 221-2, the gas flow path 221-4, and the gas flow path 221-6 is jetted from the gas jetting holes 229 bored at the arrangement positions of the gas flow path 221-2, the gas flow path 221-4, and the gas flow path 221-6 to be supplied toward the substrate 101. Further, the mixed gas of silane gas and hydrogen gas, which has been supplied to the gas flow path 221-3 and the gas flow path 221-7 is jetted from the gas jetting holes 229 bored at the arrangement positions of the gas flow path 221-3 and the gas flow path 221-7 to be supplied toward the substrate 101. Thus, in the film-forming method of this embodiment, in a stage where gases constituting raw materials for epitaxial film formation are supplied to the substrate, the respective first, second, and third gases of the source gas for carbon, the separation gas, and the source gas for silicon are supplied from the shower plate 224 toward the substrate 101 in a shower fashion in a state where they have been separated from one another.

At this time, in the film-forming method of this embodiment, timings and terms of supplying the first, second, and third gases to the gas flow paths 221-1 to 221-7 connected to the gas pipes 131-1 to 131-3 can be controlled by using the gas supply control mechanism, respectively. As a result, the film-forming method can control timings of supplying the first, second, and third gases from the gas jetting holes 229 toward the substrate 101.

Therefore, in the film-forming method of this embodiment, in the stage where an epitaxial film is formed on a substrate, the source gas for carbon, the separation gas, and the source gas for silicon can be supplied from the shower plate 224 toward the substrate 101 while they are separated from one another temporarily and the supply order of these gases can be controlled.

In the film-forming method of this embodiment, in the stage of formation of the epitaxial film, the mixed gas of propane gas and hydrogen gas, which is the source gas for carbon, is first supplied and the hydrogen gas, which is the separation gas, is secondly supplied, and the mixed gas of silane gas and hydrogen gas, which is the source gas for silicon, is thirdly supplied. The gas supplies in this order are repeated until film formation is terminated. According to such a supplying method of gases, a plurality of gases used is inhibited from being mixed to thermally react between each other on the surface of or in the vicinity of the shower plate 224.

After the film formation of the epitaxial film on the substrate 101 is terminated and the substrate 101 on which the epitaxial film has been formed is cooled to a predetermined temperature, the substrate 101 is conveyed out of the chamber 103. In that case, lifting and lowering pins are raised. After the substrate 101 is supported from the below by the lifting and lowering pins, the lifting and lowering pins are further raised to lift and separate the substrate 101 from the susceptor 102.

The lifting and lowering pins deliver the substrate 101 to a conveying robot. The conveying robot which has received the substrate 101 conveys the substrate 101 out of the chamber 103.

Further, in the film-forming method of this embodiment, as another film-forming method, a GaN epitaxial film can be formed on a substrate utilizing MOCVD method. The film-forming method in that case can be performed using the film-forming apparatus 300 of the second embodiment shown in FIG. 6 which is the film-forming apparatus having the shower plate 224 shown in FIG. 4. The film-forming method can be performed in the same manner as the case of forming the SiC epitaxial film on the substrate.

In that case, as a plurality of gases constituting raw materials for forming the GaN epitaxial film on the substrate 101, three gases can be used. As the three gases, the first gas is a source gas for nitrogen (N), for example, ammonia (NH₃). The second gas is a separation gas, for example, hydrogen gas. The third gas is a source gas for gallium (Ga), for example, trimethyl gallium (TMG) gas.

After the substrate 101 has been heated up to a temperature suitable for formation of the GaN epitaxial film, the first, second, and third gases are supplied from the shower plate 224 toward the substrate 101 while being separated from one another in a stage where a vapor-phase growth on the substrate 101 is performed.

Further, in the stage of performing the vapor-phase growth, supplies of the source gas for nitrogen, the separation gas, and the source gas for gallium which are supplied toward the substrate 101 are performed in a time-divisional fashion, and the order of the supplies can be controlled.

In the film-forming method of this embodiment, in the stage of formation of the epitaxial film, ammonia which is the source gas for nitrogen is first supplied, hydrogen gas which is the separation gas is secondly supplied, and trimethyl gallium which is the source gas for gallium is thirdly supplied. The gas supplies in this order are repeated until film formation is terminated. According to such a supplying method of gases, a plurality of gases used is inhibited from being mixed to thermally react between each other on the surface of or in the vicinity of the shower plate 224.

In the film formation of the embodiments described above, a plurality of gases which are used for formation of an epitaxial film, are high in reactivity, and easily react with each other are introduced into the shower plate while being separated from one another, and they can be supplied toward a substrate in a shower fashion in a separated state from one another without being mixed with one another.

Further, it is possible to supply a plurality of gases used for formation of an epitaxial film toward a substrate while separating the respective gases from one another spatially and temporarily. As a result, in addition to cooling the shower plate used, a plurality of gases can be inhibited from being mixed to thermally react between each other on the surface of or in the vicinity of the shower plate.

Features and advantages of the present invention can be summarized as follows.

According to one aspect of the present invention in a film-forming apparatus reaction of gases used for film formation on the shower plate can be inhibited.

According to another aspect of the present invention in a film-forming method reaction of gases used for film formation on the shower plate to be used can be inhibited.

The present invention is not limited to the embodiments described and can be implemented in various ways without departing from the spirit of the invention.

In addition to the above-mentioned embodiments, an epitaxial growth system cited as the example of a film-forming apparatus for forming epitaxial film in the present invention is not limited to these. Source gas supplied into the film-forming chamber for forming a film on the surface of a semiconductor substrate, while heating the semiconductor substrate, can also be applied to other apparatus such as CVD (Chemical Vapor Deposition) film-forming apparatus.

What is claimed is:

1. A film-forming apparatus including a film-forming chamber and a shower plate which is provided at an upper section of the film-forming chamber and through which gases supplied to the film-forming chamber pass, wherein
the shower plate has a first face directed to inside of the film-forming chamber,
a second face opposed to the first face and directed to outside of the film-forming chamber,
a plurality of gas flow paths extending between the first face and the second face along the first and second faces; and
a plurality of gas jetting holes which causes the plurality of gas flow paths and the first face to communicate with each other, wherein
the gases supplied from respective ends of the plurality of gas flow paths are jetted from the plurality of gas jetting holes toward the inside of the film-forming chamber.

2. The film-forming apparatus according to claim 1, further comprising a gas supply control mechanism controlling a timing of supplying a first gas to at least one of the plurality of gas flow paths and a timing of supplying a second gas to another gas flow path of the plurality of gas flow paths.

3. The film-forming apparatus according to claim 1, wherein the shower plate is provided with a colling mechanism.

4. The film-forming apparatus according to claim 3, wherein the colling mechanism are provided on the second face.

5. The film-forming apparatus according to claim 3, wherein the colling mechanism are provided on the side of a first face of the shower plate.

6. The film-forming apparatus according to claim 1, wherein the shower plate has a closing member for closing at least some of the plurality of gas jetting holes causing the gas flow paths and the inside of the film-forming chamber to communicate with each other.

7. The film-forming apparatus according to claim 6, wherein each of the gas flow paths extends through the shower plate in a predetermined direction along the first face, and the closing member is provided with a rod-shaped member inserted into the each of the gas flow paths to close at least some of the plurality of gas jetting holes causing the gas flow path and the film-forming chamber to communicate with each other and having through-holes formed so as to cause the remaining gas jetting holes and the gas flow path to communicate with each other.

8. The film-forming apparatus according to claim 6, wherein the closing member is a lid or a screw.

9. A film-forming method comprising:
providing a sample in a film-forming chamber;
supplying a plurality of gases to a plurality of gas flow paths of a shower plate having the plurality of gas flow paths extending within the shower plate along a first face directed to the side of the sample and a plurality of gas jetting holes bored such that the plurality of gas flow paths communicate with the inside of the film-forming chamber on the side of the first face, and
supplying the plurality of gases from the plurality of gas jetting holes toward the sample.

10. The film-forming method according to claim 9, wherein the plurality of gases include an Si source gas, a separation gas, and a C source gas.
